(19) United States
(12) Patent Application Publication
(10) Pub. No.: US 2026/0155328 A1
(43) Pub. Date: Jun. 4, 2026

(54) Control System For Ultrafast Electron Beam Microscope

(71) Applicant: Board of Trustees of Michigan State University, East Lansing, MI (US)

(72) Inventors: Chong-Yu RUAN, Okemos, MI (US); Xiaoyi SUN, Fremont, CA (US); Shen ZAO, Lansing, MI (US); Shriraj KUNJIR, Okemos, MI (US)

(73) Assignee: Board of Trustees of Michigan State University, East Lansing, MI (US)

(21) Appl. No.: 19/406,098

(22) Filed: Dec. 2, 2025

Related U.S. Application Data
(60) Provisional application No. 63/726,723, filed on Dec. 2, 2024.

(51) Int. Cl. H01J 37/075

(52) U.S. Cl. CPC H01J 37/075; H01J 2237/06333

(57) ABSTRACT

A control system for an ultrafast electron beam microscope and method of using same are provided. In another aspect, software instructions control a master control loop which suppresses low-frequency disturbances, and at least one secondary control loop which controls high-frequency radio frequency (“RF”) jitters to reduce noise, for an ultrafast electron beam microscope and method of using same. A further aspect includes a radio frequency-electron microscope and method of using same, which employs an interactive and cascading phase-locked loop for a high-brightness electron beam microscope.

### CROSS-REFERENCE TO RELATED APPLICATION

The present application claims priority to U.S. provisional patent application Ser. No. 63/726,723, filed on Dec. 2, 2024, which is incorporated by reference herein.

### GOVERNMENT SUPPORT

This invention was made with government support under DE-FG0206ER46309 and DE-SC0023633 awarded by the U.S. Department of Energy, and under 1126343 and 1625181 awarded by the National Science Foundation. The government has certain rights in the invention.

### BACKGROUND AND SUMMARY

The present application generally pertains to an electron beam microscope and more particularly to a control system for an ultrafast electron beam microscope.

Conventional single-loop analog or digital phase-lock looped configurations, commonly used in high-speed digital communication systems, achieve synchronization with low jitter. However, these systems typically operate with less emphasis on extreme temporal precision and long-term stability even under very high duty cycle rates required in ultrafast, high-throughput microscopy.

Electron spectroscopy, using a laser beam, an electron gun and a radio frequency cavity, are known. Such systems are disclosed in U.S. Pat. No. 10,607,807 entitled “Electron Spectroscopy System” which issued to common inventor Chong-Yu Ruan, on Mar. 31, 2020, and U.S. Pat. No. 9,024,256 entitled “Electron Microscope” which issued to common inventor Chong-Yu Ruan, on May 5, 2015. These patents are incorporated by reference herein. While these patents are significant advances in the spectroscopy, further improvements are desired.

In accordance with the present invention, a control system for an ultrafast electron beam microscope and method of using same are provided. In another aspect, software instructions control a master control loop which suppresses low-frequency disturbances, and at least one secondary control loop which controls high-frequency radio frequency (“RF”) jitters to reduce noise, for an ultrafast electron beam microscope and method of using same. A further aspect includes a radio frequency-electron microscope and method of using same, which employs an interactive and cascading phase-locked loop for a high-brightness electron beam microscope. Another aspect of the present electron microscope and method of using same, includes control feedback loops and software instructions configured to coordinate laser-to-laser and laser-to-RF synchronization via dual phase-locked loop subsystems, in order to create an image of specimen. In one configuration, the master and secondary loops overlap in the 0.1-10 KHz region to cancel undesired electrical and/or photonic noise in all frequencies. In yet another aspect of the present apparatus and method, an electron beam blanker operates in combination with an analog-to-digital and/or digital-to-analog converter, in a very fast manner, for an electron microscope having an RF cavity and, optionally, emitting photons in response to less than 50 fs laser pulses.

The present apparatus and method include a correlative pump-probe imaging structure, where synchronization between two mode-locked laser systems establishes the dual-probe setup: (a) a kHz repetition rate laser serving as the pump, initiating dynamic events; and (b) a GHz repetition rate laser serving as the probe, synchronized via an RF controller-based noise suppression system to form the photonic measurement unit. The second measurement unit uses photo-electron pulse sequences triggered by the GHz laser. These pulses are tuned via a GHz RF cavity lens, enabling simultaneous measurements with photon and electron probes. Together, these probes investigate dynamic events initiated by the pump pulse, offering dual perspectives on ultrafast physical processes.

Precision in dual-probe timing is achieved through digitally controlled delay sequences mediated by the RF controller. The GHz controller logic: synchronizes dual-probe timing to within sub-50 fs precision for ultrafast dynamics using optical delay stages, and extends coverage to long timescales (up to ms) using digital delay sequences at multi-GHz frequencies. This combination of optical and digital controls enables the present ultrafast electron microscopy (“UEM”) system to study phenomena spanning femtoseconds to milliseconds, addressing both ultrafast transitions and long-time relaxational processes. The RF controller cascade loop coordinates the laser-to-laser and laser-to-RF synchronization via dual phase-lock looped (“PLL”) subsystems.

The present disclosure concerns a new interactive cascade loop RF control system design advantageously offering direct support for extreme temporal precision and long-term stability, which are desirable for ultrafast, digitized beam delivery systems. The integrated design beneficially leverages a division of responsibilities, where outer, more extensive loops are tasked to suppress low-frequency disturbances and subsequent inner loops directly manage higher-frequency RF jitters. An additional feature lies in the system's cross-loop interaction over a shared-responsibility range, which strengthens robustness against a variety of noise sources. This feature ensures reliable operation in non-ideal environments, with imperfect noise isolation. The ability to adapt in such conditions makes the present ultrafast microscope highly deployable across diverse settings, such as university and industrial laboratories.

By blending noise suppression, adaptive high-speed control, and environmental resilience, the present cascade PLLs advantageously allow ultrafast microscopy systems to operate at higher levels of accuracy and stability, driving forward applications in ultrafast microscopy, and new opportunities in semiconductor metrology and fabrication processes with ultrahigh brightness digitized beams. Furthermore, the present interactive cascade loop RF control delivers higher level phase control, noise suppression, and real-time adaptability as compared to conventional approaches. Consequently, the present approach significantly elevates the temporal resolution and sensitivity in ultrafast electron microscopy using pulsed high-brightness beams. Moreover, the high-speed (close to 1 GHz level) and high-precision control of the present apparatus provide possibilities for every pulse control. Thus, the digitized high-brightness and high-throughput beam delivery enable advanced imaging and lithography capabilities.

The new cascade PLLs and control unit for ultrafast electron microscopy ensure stability across a wider frequency range and significantly improves the output signal's stability and precision. The present multi-stage design solves the traditional phase noise accumulation problem over long periods which single-loop PLLs typically struggle with. The new cascade loop system overcomes this limitation by progressively filtering out noise at each stage, to manage disturbances originating from both high-frequency RF sources and low-frequency data acquisition cycles defined by users.

This advanced control capability enables the new UEM system to surpass the resolution and sensitivity of other ultrafast systems. By incorporating RF optics, the system offers superior control over space-charge-dominated beams and phase-space manipulation. A differentiator of the new UEM is its precise regulation of laminar electron flow, which facilitates both high-current efficiency and sub-50 femtosecond temporal resolution. Additional features of the present apparatus will become apparent from the following description and appended claims, taken in conjunction with the accompanying drawings.

### BRIEF DESCRIPTION OF THE DRAWINGS

FIG. 1 is a diagrammatic view showing a timing framework for the present ultrafast electron beam microscope;

FIG. 2 is a diagrammatic view showing a DAQ controller subsystem for the present ultrafast electron beam microscope;

FIG. 3 is a software logic flow diagram showing Level-0 and Level-1 sequencing and API control operations for the present ultrafast electron beam microscope;

FIG. 4 is a perspective and partially diagrammatic view showing the present ultrafast electron beam microscope;

FIG. 5 is an electrical circuit diagram for the two-level PID system for RF phase control and noise suppression for the present ultrafast electron beam microscope;

FIG. 6 is an electrical circuit diagram for the RF control, including low-level analog PLL and cavity PID control, for the present ultrafast electron beam microscope;

FIG. 7 is a graph showing RF noise characterizations before and after applying PID feedback controls, for the present ultrafast electron beam microscope;

FIG. 8 is a graph showing noise power spectrum and interactions between the two PID control loops in the 10 Hz to 1 kHz range, for the present ultrafast electron beam microscope;

FIG. 9 is a graph showing noise time sequences obtained by a PID-0 phase detector with increasing levels of PID control, for the present ultrafast electron beam microscope;

FIG. 10 is a graph showing phase noise histograms obtained from corresponding time sequences of FIG. 9, for the present ultrafast electron beam microscope;

FIG. 11 presents graphs of accumulated RMS noises derived from integrating the noise power spectrum obtained from the time sequences of FIG. 9, for the present ultrafast electron beam microscope;

FIG. 12 is a graph showing RF phase stabilities for the present ultrafast electron beam microscope;

FIGS. 13-16 are graphs showing UEM and UED performance from optically tuning a condenser system, for the present ultrafast electron beam microscope;

FIGS. 17 and 18 are graphs showing impacts from RF instabilities on temporal and spatial resolutions, for the present ultrafast electron beam microscope;

FIG. 19 is a microphotograph showing coherent phonon dynamics probed by ultrafast diffraction modality with a diffraction pattern from an exfoliated 1T-TaSe₂ sample, using the present ultrafast electron beam microscope;

FIG. 20 is a graph showing intensity modulations registering the coherent phonon dynamics and incoherent channels, for the present ultrafast electron beam microscope;

FIG. 21 is a diagram showing the high-speed DAQ for the present ultrafast electron beam microscope;

FIG. 22 is a diagram showing a probe signal capture of the high-speed DAQ for the present ultrafast electron beam microscope;

FIG. 23 presents graphs showing multi-modality perspective on phase transition dynamics, for the present ultrafast electron beam microscope; and

FIG. 24 is a perspective view showing an RF cavity heating and cooling assembly for the present ultrafast electron beam microscope.

### DETAILED DESCRIPTION

A preferred embodiment of a control system for an ultrafast electron beam microscope (“UEM”) includes a femtosecond photoelectron gun, which is driven by a fs laser and harmonic generator pulse shaper for high-brightness beam generation. The present system further includes an energy-compression radio frequency (“RF”) cavity. The RF cavity is coupled to the gun through mode-matching optics and an energy filter to produce and emit monochromatic electron beams, containing a bunch of electrons in each pulse or shot, for the spectroscopy process in a vacuum chamber. The system also includes a seed fs oscillator, a phase-lock loop, a master RF clock and an RF amplifier.

Furthermore, the present system employs a field-programmable gate array (“FPGA”) paired with fast data converters that interface directly with the RF cavity. This FPGA-based controller is optimized to suppress local phase noise within the cavity's bandwidth. Proximity-coupled to the UEM column, a high-speed low-level RF (“LLRF”) controller, referred to as PID-1, serves dual roles. A second level of control employs an analog phase-locked loop (“PLL”) system, featuring a 4 MHz digitizer, averaging over 1,000 samples to achieve the precision needed to run the proportional-integral-derivative controller (“PID”).

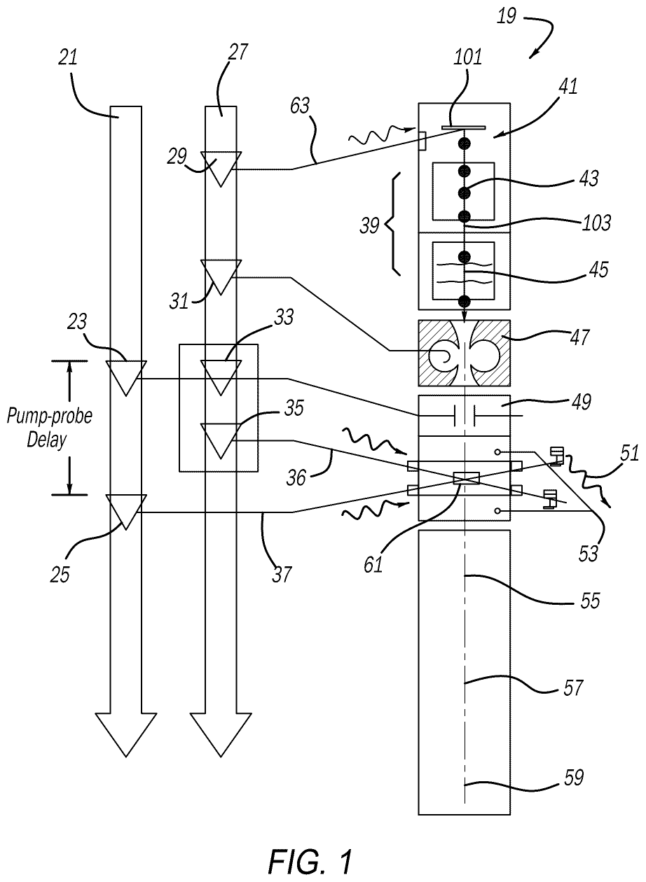

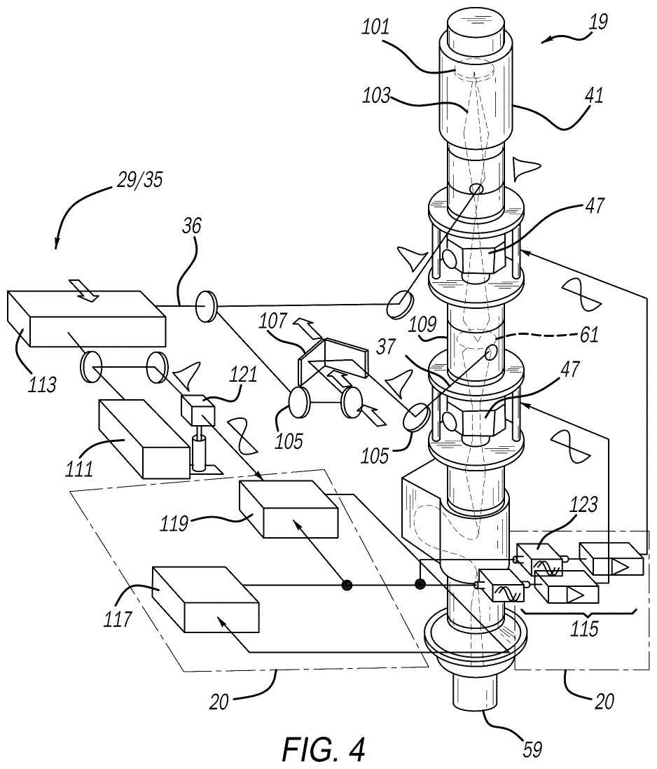

More specifically, FIGS. 1 and 4 depict the dual-probe physical setup, illustrating the synchronization of lasers, logic and data flows, and their integration with optical detection systems. A preferred embodiment of the present UEM apparatus 19 includes a pump-probe logic control 21 via a controller 20 with a dual-probe selection 23 via a selector and a pump-pulse sequence 25 via a sequencer, with a pump-probe digital delay therebetween. The present apparatus further includes GHz data flow 27 with a GHz laser drive 29 to deliver GHz probe electron pulse, a GHz RF cavity drive 31, a beam blanking control 33, a GHz laser probe pulse 36 and a KHz laser pump pulse 37. A photo-electron emitter gun 41 emits electrons through a gun lens/accelerator 43, a condenser lens system 45, an RF cavity/lens 47, an electron beam blanking system 49, multiple spaced apart photon detectors 51, objective lenses 53, a specimen 61, an intermediate lens 55, and a projection lens 57, which are received by an electron detector 59. The gun lens/accelerator and condenser lens system are part of a GHz electron pulse delivery assembly 39.

Electron beam blanking system 49 includes a streak camera which acts to selectively deflect the electron beam from entering the specimen chamber. It acts at a high speed with the RF cavity. More particularly, the streak camera is a streak-camera-style high-voltage electrode, acting as a deflection electrode that produces a time-varying voltage ramp upon receipt of an external trigger. In the present system, this electrode structure is repurposed to control beam blanking with high temporal precision. A novel element is the integration of a high-speed trigger derived from the present GHz RF synchronization unit, which is locked to the electron beam generation sequence. This ensures tight temporal control over when the beam is allowed to reach the sample chamber, thereby functionally providing a high-speed RF timing anchor.

The UEM is preferably a transmission electron microscopy (“TEM”) apparatus having an electron beam column including a substantially flat (≥100 μm) photocathode 101 and an anode electrode, which extract photoelectrons from the surface and accelerate them to form the initial electron beam 103 emitted by electron gun 41. An electron gun lens and an aperture control and set the beam diameter. Two condenser stages with lenses and manage the beam's lateral expansion and demagnify the beam waist as needed. Additionally, radiofrequency cavity 47 acts as a longitudinal condenser to compress the electron pulse. These lenses maintain the high-density beam formation and control the aspect ratio of the pulse disk delivered to specimen 61 and objective system.

Externally, a drive laser system 29 is coupled to photo-electron gun 41 as the photoemission drive, with variable intensity and beam size controlled by a filter and expander sets. An optional spatial light modulator (“SLM”) can be applied to ensure a homogeneous laser wavefront. For pump-probe ultrafast measurements, pump laser 35 emits a laser beam pulse 37 via a separate path with mirrors 105 and reflective time delay optics 107, such that laser pump beam 37 is received within a specimen chamber 109. The lasers include an oscillator 111 and an amplifier 113.

Controller 20 and its software instructions cause an RF power supply to send RF power to an RF pickup 114 within RF cavity 47, also known as the longitudinal lens. Synchronized RF control circuit 115 further includes a master RF clock 117, a phase-locked loop circuit 119 and a fast diode 121 connected to the drive laser system, and RF amplifiers 123. The fs laser system provides timing to pump pulse initiating material transformation as well as for seeding the RF signals sent to the RF cavity that delivers the short electron probe pulses.

The electrons passing through the first condenser lens thereafter pass through the RF cavity, pass through a second condenser lens, through an aperture array, through an upper objective lens and impact the specimen on its holder. A lower objective lens, a lower objective aperture and a transfer lens system pass the image from the specimen to the detector. Each laser pulse emitted by the laser preferably has a duration less than 100 fs, and more preferably less than 50 fs. The laser pulses preferably have a repetition rate faster than 1 KHz, and more preferably faster than 1 GHz, at the microscope. A preferred CW beam photoemission brightness is at least 3.67×10⁷ A·cm⁻²sr⁻¹ with a preferred total beam current of at least 1.60 μA.

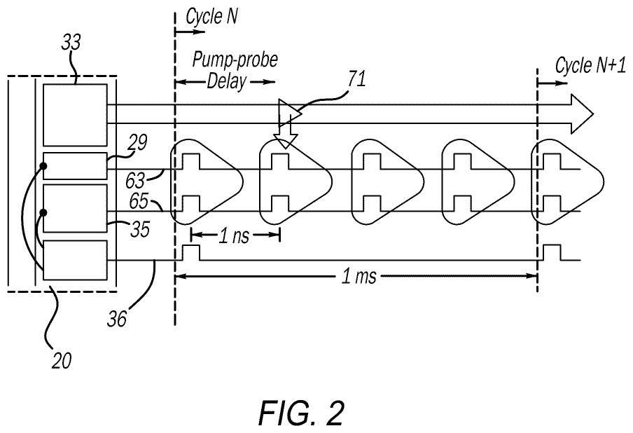

FIGS. 2, 5 and 6 highlight the high-speed digital logic control and data corrections enabled by the present RF controller unit. Two embedded PLL systems manage laser-to-laser and laser-to-RF synchronization, ensuring stability and precision.

FIG. 2 zooms into the GHz data acquisition (“DAQ”) controller subsystem. This FPGA-based module handles sub-ns gating and high-speed data captured from the optical probe track. Synchronization is achieved through dual-loop PLL-based cascade controller 20, which governs laser-to-laser and laser-to-RF alignment. High-speed optical controller 35 drives the continuous GHz-spaced probe pulse train 65, operating in coordination with the pump laser source 36. Alternatively, a single probe delay within each pump cycle can be selected by the probe-pulse selector 71, thereby generating a dual-probe track. In this configuration, the beam-blanking control is synchronized with the probe selector to isolate the desired electron-probe pulse from the GHz-spaced electron-pulse stream 63 produced under the laser-drive control 29. These units interface with fast photodetectors whose outputs are digitized and streamed to the central control PC for either every-pulse recording or gated selection-based averaging. This integrated platform provides a beneficial solution to a traditional limitation in ultrafast electron microscopy: the inability to resolve ultrafast and long-duration dynamics simultaneously in a coherent and synchronized fashion. In contrast, by leveraging advanced FPGA-based control and DAQ technologies in the present apparatus, this system expands the temporal range and resolution of ultrafast microscopy, enabling a comprehensive mapping of nonequilibrium material responses from femtoseconds to milliseconds.

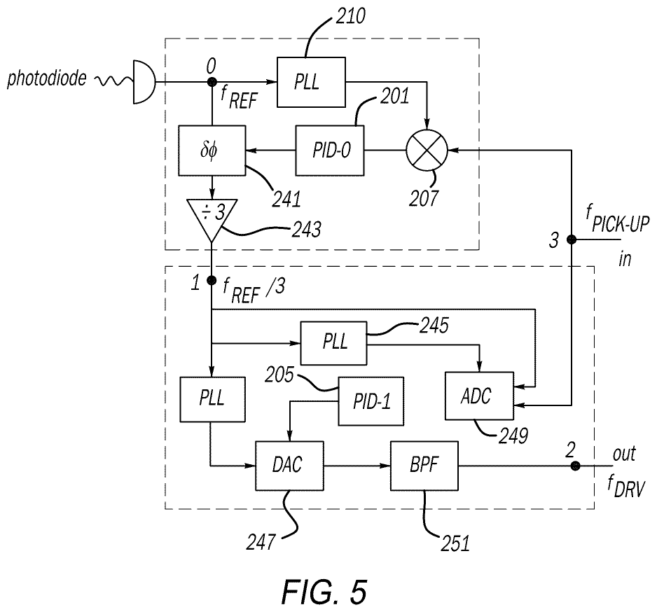

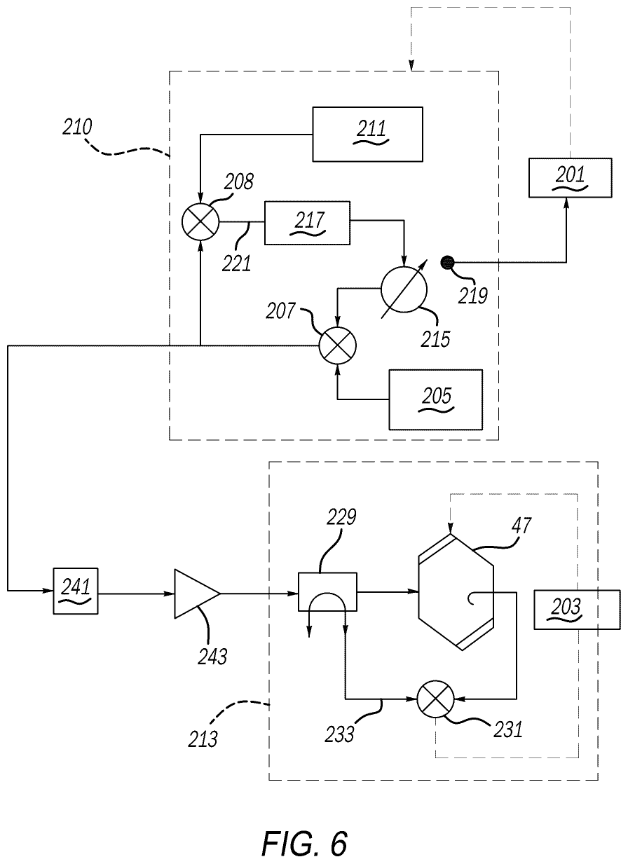

FIG. 5 describes the present control system which employs a master programmable controller 201, designated as PID-0, and a slave programmable controller 203, designated as PID-1. These controllers may be separate or an integrated unit with each other and/or controller 20. The controllers each include a microprocessor configured to operate programmed software instructions, and non-transient RAM or ROM memory or field programmable gate array (FPGA) within which the software is stored. FIG. 6 illustrates the integrated RF control system, which incorporates both a low-level RF (“LLRF”) software loop 210 and a cavity-PLL software loop 213. Together, these loops coordinate the control logic that transfers a synchronized low-level RF signal to the high-level amplified drive used to operate the RF cavity. The LLRF software loop 210 includes an analog PLL implemented as part of the PID-0 controller, responsible for laser-RF signal synchronization. In this loop, a mixer 207 combines the output of a voltage-controlled oscillator (“VCO”) 215 with a stable RF reference source 205 to generate the target RF signal. To maintain synchronization with the laser reference 211, the mixed signal is compared against the laser timing input using the mixer 208. The resulting error signal is processed through an electrical loop filter 217, producing a correction voltage that servo-controls the VCO. A temperature sensor 219, mounted on the analog-PLL circuit enclosure, provides feedback to a temperature controller 201 to minimize thermal drift in the PLL electronics. In the cavity-level PLL software loop 213, a directional coupler 229, the RF cavity 47, and a phase detector 231 form an electrical feedback circuit 233 for stabilizing the cavity resonance. The phase detector output—serving as a temperature-dependent error signal—is fed to a temperature controller 203 to maintain the cavity at its resonance frequency and locked to the input low-level RF signal. A voltage-controlled attenuator 241 and an +80 dB power amplifier 243 provide the appropriate gain and coupling between the low-level and cavity-PLL loops 210 and 213, ensuring stable high-power operation of the RF cavity.

This multi-stage control scheme is designed to perform jitter correction and disturbance rejection, significantly improving the temporal resolution and sensitivity of ultrafast electron microscopy systems. The integrated architecture incorporates two or more phase-locked loops, with each loop assigned to manage a specific frequency range. These loops overlap over a finite frequency window, creating a shared responsibility regime to ensure smooth and precise control. In this configuration, the higher-frequency PLL operates nested within the lower-frequency PLL to provide seamless transitions and enhanced stability. This architecture achieves exceptional precision, delivering temporal resolutions below 50 femtoseconds and spatial accuracies at the 10-femtometer scale.

The two-level cascade design, as illustrated in FIG. 5, adopts an integrated approach, combining analog and digital phase-locked loops to achieve both long-term stability and real-time high-speed control. The circuits include the electronic components of: phase detector 207, a voltage-controlled phase shifter 241, a frequency divider 243, a phase-locked loop chip 245, a digital-to-analog converter 247, an analog-to-digital converter 249 and a band-pass filter 251. f_{REF} is the reference frequency selected from the frequency comb of the laser, used as the reference frequency for the RF system; f_{DRV} is the driving frequency sent to the RF cavity that compresses the electron beam; and f_{PICK-UP} is the frequency of signals at the pickup port.

The inner loop handles high-speed operations, utilizing a System-on-Chip (“SoC”) field-programmable gate array (“FPGA”) paired with fast data converters that interface directly with the 1.013 GHz RF cavity. This FPGA-based controller is optimized to suppress local phase noise within the cavity's bandwidth of approximately 0.1 MHz, ensuring precise performance.

The second level of control employs an analog PLL system, featuring a 4 MHz digitizer with averaging over 1,000 samples to achieve the precision needed to run the PID. With a sub-millisecond detection window, the system can identify noise spectra beyond 1 kHz. Operating at a 10 Hz loop rate, this level of control (PID-0) ensures the necessary phase stability for long-term operations. PID-0 also serves as the master feedback loop, overseeing the entire RF circuit, while it compensates for phase differences Δφ₀₃ measured between the laser front end and the RF pickup port, feeding phase corrections into the PID-1 subsystem.

Meanwhile, PID-1 focuses on local phase noise correction, compensating for Δφ₁₃, measured between the input signal to the high-speed low-level RF (“LLRF”) controller and the signal at the cavity's pickup port. Together, this hierarchical control architecture ensures the stability, precision, and adaptability required for the advanced performance of the ultrafast electron microscopy system. The entire RF system integration also includes the self-diagnosis loop and the servo-loop for maintaining the RF cavity resonance with the provided signals.

To mitigate the additive phase noise in the reference clock to the LLRF controller, the system incorporates a dual-loop jitter cleaner at the Reference point 1. The first stage inside the jitter cleaner is a phase locked loop (PLL1) that operates as a jitter attenuator, configured with a narrow loop bandwidth (typically <100 Hz) to act as a steep low-pass filter for phase noise. This loop disciplines an external, ultra stable Voltage-Controlled Crystal Oscillator (“VCXO”), effectively rejecting the high-frequency spectral components of the input jitter while tracking the average frequency of the source. The cleaned output from the VCXO then serves as the low-noise reference for the second stage (PLL2), which functions as a frequency synthesizer. PLL2 employs a wider loop bandwidth to suppress the intrinsic phase noise of the internal Voltage-Controlled Oscillator (“VCO”), thereby generating a stable, low-jitter clock signal synchronized to the reference clock. The PLL2 VCO clock is further divided down to generate clocks for analog to digital converter (“ADC”), digital to analog converter (“DAC”) and FPGA.

In addition to the PID-0 and PID-1 subunits integrated into the cascade-loop design, an additional cavity-level PLL loop is incorporated as a self-stabilizing servo loop to maintain RF cavity resonance without relying on mechanical tuners, as can be observed in FIG. 6. While PID-1 provides amplitude control to ensure the cavity field remains stable, any resonance frequency drift from the locked frequency increases the overhead for high-level RF circuit control. Otherwise, significant drift can cause the PLL to run off-track, potentially leading to system shutdown.

Returning to the beneficial jitter control features, cavity PLL 213 effectively mitigates “detuning-induced” RF timing jitter (T_{RF}), especially under environmental conditions where room temperature may vary by up to 1° C. during long-term operation. Without the cavity PLL, such fluctuations induce phase drift, reducing performance. But when the cavity PLL is active, low-frequency fluctuations are fully suppressed, providing a significant improvement over the free-running cavity.

The nested feedback loops detect and compensate for the active noise sources over their own detectable spectral ranges. The cascade loop design could synergistically reduce the noise floor as well as ensuring the longer-term stability through the existence of a shared responsibility spectrum region for joint optimization. This spectral region is allocated in the most active frequency domain from 1 Hz to 1 kHz.

The Level 0 master loop acts as the primary interface between user inputs, the laser system's output (reference signal), and the RF cavity lens output (corrected signal). Its purpose is to synchronize the reference signal from the laser system with the RF signal from the UEM cavity. The inputs and processing include:
User inputs are interpreted as set points to drive the synchronization process.
The PLL processor in Level 0 manages:
   Low-frequency compensation using a PID disturbance rejection algorithm, active over a frequency range of <0.001 Hz to 10 kHz.
   Set points adjusted for slow user timescales.
The output is a refined control signal passed to Level 1 for high-frequency noise suppression.

The Level 1 slave loop is implemented on an FPGA-based PLL system and focuses on high-frequency noise suppression, processing signals in the 0.1 kHz to GHz range. The signal processing includes:
Input signals from Level 0 and the RF cavity are:
   Demodulated into amplitude and phase components by a high-frequency analog-to-digital converter.
   Processed using a high-frequency PID algorithm to correct jitter and disturbances, meeting user-defined set points for phase and amplitude.
      Output control includes:
The jitter-reduced signal is fed to an RF amplifier, which drives the UEM RF cavity for precise operation.
The FPGA's parallel processing capabilities ensure efficient real-time adjustments.

The Shared Responsibility Frequency Window (“SRSW”) spans from 0.1 kHz to 10 kHz, where both Level 0 (master loop) and Level 1 (slave loop) collaboratively address disturbances detected by the UEM RF cavity. Within this frequency range, the cascade-loop design ensures that noise build-up from high-frequency corrections in Level 1 is effectively managed by the master-loop PLL in Level 0. This overlapping responsibility provides robust noise suppression across a broad frequency spectrum, ensuring a stable and reliable operating environment for the UEM system.

Advantages of the present cascade-loop design include:
Broadband Noise Suppression: Covers a wide frequency range, mitigating disturbances from both high-frequency and low-frequency sources.
User-Driven Flexibility: Seamlessly integrates user inputs for customized operation.
Precision and Stability: Interactively combines low-frequency PID algorithms with FPGA-based high-frequency processing for enhanced synchronization and minimal jitter.
Real-Time Operation: Efficient parallel processing in Level 1 ensures rapid and accurate responses to high-frequency jitters.

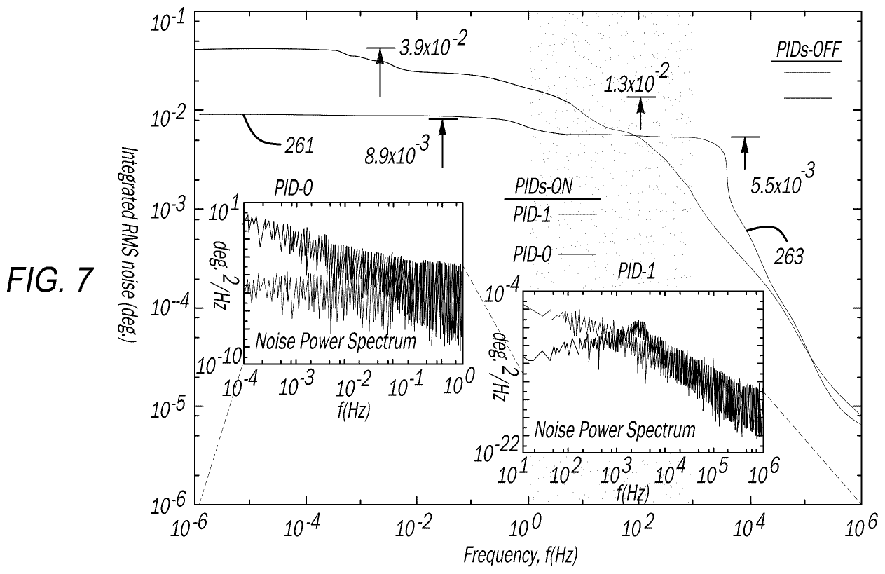

FIG. 7 depicts RF noise characterizations before and after applying PID feedback controls. The main graph shows the integrated RMS noise measured from PID-1 & PID-0 loops separately, wherein the performance with active PID correction and without PID correction are compared. The insets show the corresponding noise power spectrum plotted wherein the dotted area represents the shared responsibility region for the two PID systems.

System-wide, the present apparatus unifies the two field-programmable gate array (“FPGA”)-based controller units under a unified master user interface that automatically coordinates task delegation across both units. The dual-FPGA-based platform enabling high-precision temporal synchronization and deep-window data acquisition for ultrafast electron microscopy. The system combines two tightly integrated, FPGA-accelerated subsystems: (1) a high-precision laser-to-RF synchronizer capable of sub-10 fs stability to align femtosecond laser pulses with the UEM RF cavity, and (2) a GHz-level high-speed DAQ system that enables electron and optical probes to access temporal dynamics not only in the ultrafast range (i.e., 1 fs to 100 ns), but also extending into long-duration processes across microsecond to millisecond scales (i.e, ≥1 μs). This architecture allows for continuous or pulse-selected probing of non-repetitive or slowly evolving dynamics, overcoming current limitations posed by optically delayed pump-probe approaches.

At the core of this system is a timing and acquisition hierarchy that governs dual data pipelines across two probe tracks. The outermost layer is the user-defined acquisition window T_{acq}, typically spanning seconds, which encompasses repeated pump-probe cycles. In Track I, ultrafast dynamics from sub-10fs up to the pump repetition period Tₚᵤₘₚ (e.g., 1 ms for a 1 kHz pump) are probed using femtosecond electron pulses, where temporal delays are introduced via optical delay stages. These measurements are typically limited by sample recovery time and detector download latency, and are orchestrated via a central workstation that controls UEM beam gating, RF-lens synchronization, and 2D electron imaging.

In Track II, the present system enables life-cycle probing over the entire pump period (from 1 ns to 1 ms—the pump cycle duration) by employing an optical probe laser operating at GHz repetition rates (e.g., 80 MHz to 1 GHz). The shared pump laser initiates both probe tracks simultaneously, but Track II leverages two FPGA-controlled data pathways: the first captures every pulse from the high-repetition-rate probe laser at fixed ns intervals using a high-speed streaming DAQ system; the second applies electronically gated acquisition to select and record only specific probe pulses at sub-nanosecond delay increments within each pump cycle. Over the full acquisition time T_{acq}, this gated approach reconstructs the full pump-probe delay space from ns to ms, using only selected pulses without the need to store or process the entire data stream. This is desirable for enabling correlation with the UEM Track I data, where full-frame image acquisition cannot occur at the laser repetition rate.

The present dual-mode acquisition strategy overcomes limitations of traditional optical delay stages, which cannot access dynamics beyond several nanoseconds, and camera-based detectors, which cannot record on every laser cycle. By coordinating both data pipelines within a central control framework, the present system allows simultaneous probing of fast transient responses and long-lived relaxation processes, with programmable resolution and time coverage. The two tracks are unified under a shared timing controller, ensuring all measurements—whether every-pulse or delay-selected—are temporally correlated and traceable to the same pump excitation cycle.

From a hardware standpoint, the present system includes three integrated modules: (A) A central workstation with user interface, which configures acquisition time T_{acq}, delay sequences for Track I and II, and sub-divided time cycles within Track II; this controller also mediates communication with detectors, orchestrates gating logic, and retrieves data from both pipelines. (B) A laser-RF synchronization unit, built on FPGA with phase-locked loops and cascade PID controllers, which align the GHz laser, RF cavity, and femtosecond pump laser with sub-10fs stability. And, (C) A GHz DAQ and timing control unit, also FPGA-based, responsible for issuing precise gating signals, acquiring optical data streams, and implementing both continuous and delay-selective readout strategies.

Referring again to FIG. 1, in Track I, the system includes pump-probe logic control 21, a UEM beam selection module 23 (via gate trigger), and pump-probe delay control 25 implemented via optical delay stage. This path enables sub-10fs to several-ns delay probing using the femtosecond electron beam. Track II contains GHz data flow infrastructure 27, with GHz laser drive 29, GHz RF cavity drive 31, beam blanking control unit 33, GHz optical probe pulse source 35, and KHz-range pump laser 37. Track II optical signals are collected by photodetectors 51 for downstream processing.

A high level API-based automation protocol for the present dual-FPGA UEM apparatus and method are set forth as follows. This automation protocol coordinates ultrafast electron microscopy acquisition across two data tracks: (a) Track I: Ultrafast pump-probe delays (sub-10 fs to ns) using optical delay stages; and (b) Track II: Extended time-scale probing (ns to ms) via electronic gating and GHz laser probing, driven by RFSoC-based DAQ and control logic. Each track is orchestrated via API calls from a central control workstation, interfacing with: laser-to-RF synchronizer with dual-loop cascade PLL; GHz-level data acquisition engine using hybrid PL-PS streaming and accumulation; optical delay line actuator for Track I; beam blanker, RF cavity lens, and emission control (via PCIe-attached DAQ); and GUI for real-time experiment setup and live interaction. Users initiate an experiment by specifying key parameters such as total acquisition time (T_acq), desired probe delay schemes, and the data acquisition mode (e.g., single-pulse selection vs. every-pulse streaming). This triggers the initialization of two FPGA-accelerated subsystems: (a) a laser-to-RF cascade-loop synchronizer that ensures sub-10 fs timing precision between the laser and UEM RF cavity; and (b) a GHz-level data acquisition engine that captures photodiode signals with ns resolution across pump-probe cycles spanning from ns to ms. The data acquisition engine is preferably built on a Xilinx RFSoC (“Radio Frequency System-on-Chip”) platform.

In Track I, ultrafast dynamics are measured using an optical delay stage that physically adjusts the pump-probe timing to scan femtosecond-to-nanosecond timescales in an automated sequence, while the UEM camera acquires electron images at each delay point. In parallel, Track II captures long-duration processes using the FPGA-driven DAQ system, which electronically selects a single probe pulse—or bypasses selection to continuously stream GHz-spaced optical dual-probe pulses—to interrogate slower dynamics within each pump cycle. A segmented capture strategy, controlled by APIs in a PYNQ environment, enables data to be accumulated or streamed in real-time with full synchrony between tracks. The automation logic handles triggering, DMA transfers, coherency checks, accumulation and final data export, thereby ensuring that measurements across both ultrafast and lifecycle regimes are integrated into a unified, programmable experimental workflow.

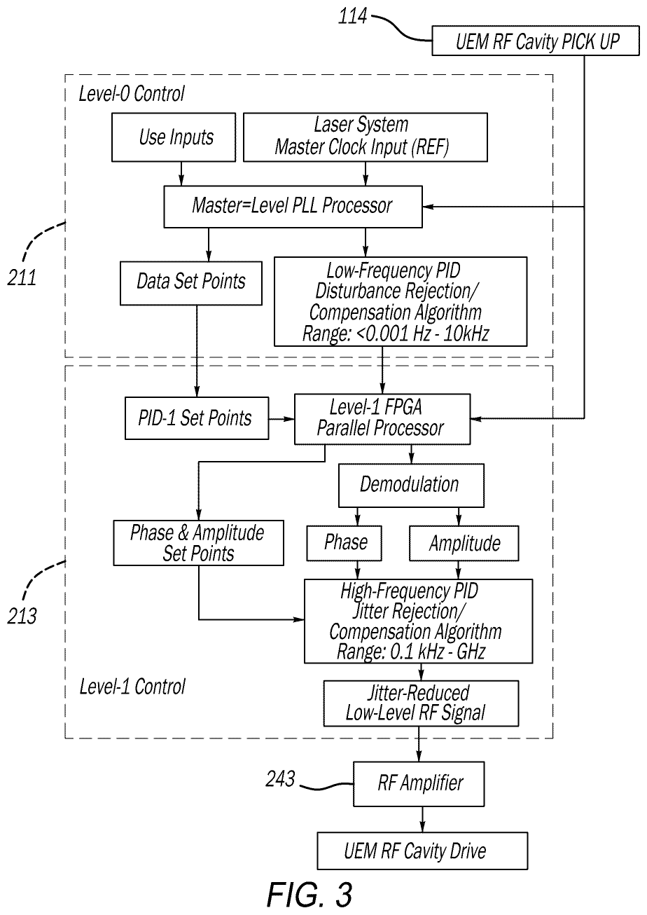

A logistics workflow for the first FPGA subsystem includes the laser-to-RF cascade-loop synchronizer, with a high-rate digital control, fixed-point FPGA implementation and extensible optimization algorithms. This can be observed in FIG. 3. This first FPGA-accelerated subsystem implements a cascade-loop timing synchronization architecture that aligns the femtosecond laser oscillator with the UEM RF cavity lens with sub-10 fs stability, achieved through the coordinated use of an analog PLL and slow software PID loop (Level 0) and a fast FPGA-resident loop (Level 1). This FPGA-resident loop beneficially has a high-loop-rate digital implementation, on the order of multi-MHz, which is desired to suppress high-frequency RF noise intrinsic to ultrafast electron beam compression. For example, the present loop employs ≈5 MHz-class loop rates to counteract fast amplitude and phase disturbances in the RF cavity. Achieving this level of real-time correction uses a fixed-point control arithmetic architecture running entirely in FPGA fabric, avoiding the computational latency of floating-point operations used in software-based low-rate control. Thus, this loop employs a high frequency regime and integrates it into a cascaded dual-loop structure designed explicitly for UEM-RF-laser synchronization.

At the system level, Level 0 operates on long time scales, where the processor-based PID routines (running <10 kHz) correct slow drifts arising from thermal fluctuations, environmental vibrations, temperature drift or user-initiated setpoint changes. This loop continuously aligns the RF cavity frequency and phase to the laser reference, passing a coarse-corrected control signal to the high-speed FPGA loop. Level 1, implemented entirely in FPGA logic, receives the demodulated amplitude and phase error from high-speed ADCs and executes the fixed-point control algorithm at MHz-class rates. This loop suppresses fast jitter components in the 0.1 kHz-1 GHz frequency band, protecting the femtosecond timing coherence required for electron pulse compression and beam stability. Moreover, the two loops together define a Shared Responsibility Frequency Window, wherein Level 0 damps low-frequency drift and Level 1 eliminates high-frequency jitter, ensuring the corrections do not interfere or accumulate across timescales.

The present architecture is designed to be algorithm-agnostic and extensible. While the present implementation uses PID and ADRC structures, the FPGA control core includes programmable logic blocks that can be repurposed for more advanced controllers as the system evolves. For instance, if model information becomes available, model predictive control (“MPC”) could optionally be implemented within the FPGA fabric to anticipate future disturbances, or iterative learning control (“ILC”) could be deployed to reject periodic timing disturbances. With this dual-loop approach, high-frequency digital control, and algorithmic flexibility, the synchronizer achieves a timing stability and correction bandwidth far beyond conventional RF-laser lock systems. This capability is advantageous for maintaining femtosecond electron pulse integrity over acquisition windows ranging from microseconds to hours and forms a foundational component of the broader dual-probe UEM architecture.

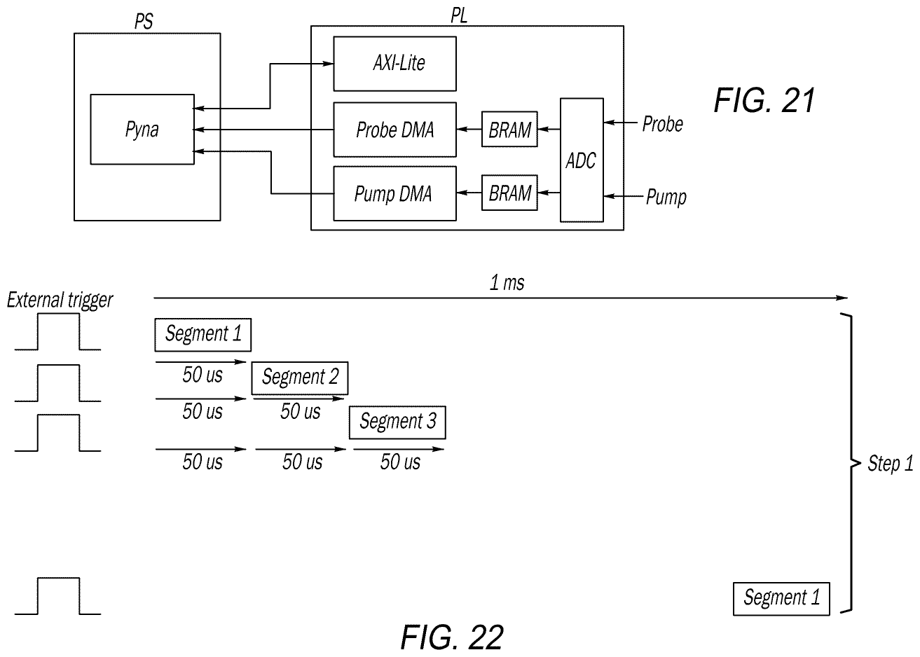

FIG. 21 is a diagram showing high-speed DAQ, where the system is partitioned into two primary components: the hardware capture engine in the programmable logic (“PL”) and the software controller in the processing subsystem (“PS”). Furthermore, FIG. 22 presents the probe signal capture in the high-speed DAQ configuration.

The logistics workflow for the second FPGA subsystem, which includes a GHz-level RFSoC data acquisition engine, will next be described. It provides continuous or electronically gated ns-resolution probing over ns→ms→seconds. The second subsystem implements a deep-window GHz DAQ architecture, preferably using a Xilinx RFSoC platform. This integrated hardware includes multi-gigasample-per-second (“GSPS”) analog-to-digital converters, digital-to-analog converters, a programmable logic fabric comprising an FPGA, and an ARM-based processing subsystem. The combined system is configured to perform parallel signal acquisition, segmentation, and accumulation for both optical and electron-based detection signals, with the flexibility to operate in both continuous and gated acquisition modes.

In operation, this subsystem is configured to acquire analog signals from two photodiode channels, designated as signal and reference, generated by optical probe pulses that interrogate the material system following femtosecond pump excitation. In one mode, the system captures signals from every probe pulse occurring at ˜1 GHz intervals within each millisecond-long pump cycle. In another mode, a digital gating mechanism selectively captures individual probe pulses at programmable delay offsets, such that over a complete user-defined acquisition window (T_acq), the full temporal response of the sample is reconstructed with nanosecond resolution.

A significant challenge in this domain lies in the volume and rate of data generated. A single 1 ms acquisition window sampled at 2.45 GSPS and 14-bit resolution can generate over 2.4 million samples, corresponding to more than 157 Mbits of data per channel. On-chip Block RAM (“BRAM”) available in the FPGA fabric is insufficient to accommodate such deep buffers. Thus, to address this limitation, the present system implements a hybrid PL-PS architecture wherein the FPGA handles high-speed real-time data capture over narrow segments (e.g., 50 μs duration), while the PS manages data accumulation and storage within a high-capacity Double Data Rate 4 (DDR4) memory module.

The segmented acquisition procedure is orchestrated as follows. Upon receipt of a hardware trigger synchronized to the pump laser, the programmable logic activates a finite-state machine (“FSM”) that initiates acquisition of a 50 μs signal segment into BRAM. The process is repeated with incremental delay offsets across N segments (e.g., 20), each offset corresponding to an increased post-pump delay. If the storage capacity of the FPGA and BRAM is exceeded, then the 1 ms window is broken down into smaller segments (such as 20 segments of 50 μs) which can be changed to 100 segments of 10 μs each, 1000 segments of 1 μs each, or other amounts depending on the on-chip BRAM storage availability. Over M pump cycles (e.g., 10,000), these segmented acquisitions are averaged in DDR4 memory under supervision of the PS, thereby reconstructing the full temporal response with improved signal-to-noise ratio.

In parallel to the primary acquisition path, a second FSM implemented in the PL is configured to capture high-speed signal transients within narrow windows (e.g., 20 ns, or changed to less or more data) aligned to specific probe pulses. This secondary FSM operates independently but is synchronized to the same pump trigger, allowing simultaneous acquisition of slow dynamics and fast transients across dual time scales. The separation of tasks into independent FSM pathways enables non-blocking acquisition of coarse and fine temporal features.

The programmable system executes high-level acquisition control, memory management, and user interaction. Configuration parameters, including the number of steps, delay offsets, trigger timing, and segment duration, are defined via a user-accessible interface-GUI. The PS monitors acquisition status in real-time, manages DMA transfers between BRAM and DDR4, validates data headers for synchronization consistency, and performs coherent accumulation and post-processing of the acquired data. The resulting system thus enables flexible, user-defined acquisition strategies that can access both short-lived and long-duration dynamic phenomena. The platform supports (1) continuous streaming of probe pulse signals at full repetition rate for real-time material response monitoring, and (2) digitally-controlled selective gating for sparse sampling with reduced bandwidth requirements. The combination of segmented buffering, real-time FPGA logic, and high-capacity off-chip accumulation provides a scalable and extensible DAQ framework for high-repetition-rate ultrafast microscopy.

In summary, Subsystem I (Synchronizer) provides:
Dual-loop cascade PLL with shared frequency responsibility;
Digital high-frequency jitter suppression up to GHz;
FPGA-accelerated parallel PID execution; and
Achieves <10 fs synchronization precision.

In summary, Subsystem II (DAQ) provides:
FPGA-resident dual-FSM capture engines for 20 ns and 50 μs windows;
Hybrid PL-PS segmented accumulation eliminating BRAM limits;
Two DAQ modes: every-pulse and ns-gated; and
Extends probe windows from fs→ns→ms→seconds with ns precision.

Accordingly, the second cascade subsystem overcomes on-chip memory limitations and synchronizing parallel acquisitions of transient signals with sub-50 fs precision. It enables temporal multiplexing and statistically robust averaging over millions of pump-probe cycles, all within a high-speed, low-latency architecture. This configuration thereby achieves resolution of both ultrafast and long-lived dynamic phenomena in materials systems, and may be applied in broader photonic, quantum, or biological imaging platforms requiring similar temporal breadth.

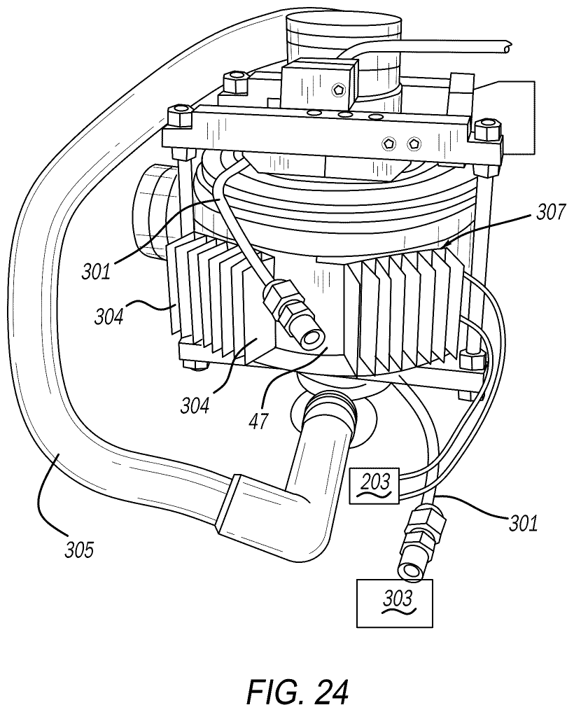

Reference should now be made to FIGS. 6 and 24 for a discussion about an optional temperature control aspect of RF cavity 47 of the present UEM apparatus, wherein the RF cavity is paired with active thermal management components. Cooling coils or conduits 301 are embedded within prefabricated channels machined into the top of the metallic walls of RF cavity 47. The cavity walls are preferably constructed from Oxygen-free high conductivity (“OFHC)” copper. Cooling coils are tightly buried in the walls to ensure efficient thermal contact and minimal spatial footprint. These coils are coupled to a pump and reservoir of a chiller and/or heat exchanger system 303, via hoses. Cooling coils 301 circulate a liquid coolant, such as water, and serve as the basic heat sink to efficiently carry away the substantial heat generated by the active RF cavity. This is greatly desirable in the present situation since the RF cavity acts as the longitudinal lens for the ultrafast electron microscope, a function that requires significant RF power and generates thermal load which must be dissipated to maintain operational stability.

Metallic TEC plates or fins 304 outwardly project from an exterior of the RF cavity walls. This provides additional heat sink dissipation. Moreover, a vacuum hose 305 couples an inside of UEM adjacent RF cavity 47, to a vacuum pump.

Four thermoelectric modules 307 serve as temperature actuators, mounted directly on RF cavity 47. A voltage signal from phase detector 231 feeds into PID controller 203, which drives thermoelectric modules 307 to actively adjust the cavity's resonance frequency (f₀) by modulating its temperature. With this system, the RF cavity's timing and power stabilities are maintained within 550 fs and 510-3 levels, respectively, aided by sub-50 mK active temperature stabilization across the electronics and the cavity. This allows cavity to track input frequency changes from the low-level PLL, keeping the cavity consistently on resonance.

The phase detector compares phase inputs between forward and cavity pickup signals to produce an output voltage proportional to the phase difference. The controller includes an integrated TEC driver and reads input from the thermal sensors (e.g., thermistors). The controller compares sensed input (the repurposed RF phase difference) to a desired setpoint or threshold value, and then adjusts output power accordingly. In other words, the phase-detector output serves as a proxy temperature sensor that provides cavity-temperature information to the controller. Based on this information, the controller automatically determines whether the cavity has drifted beyond a predetermined or stored desired threshold value, and if so, automatically adjust a cooling system performance and/or other equipment characteristic accordingly.

The temperature of the RF cavity can significantly affect the performance of the RF signal which undesirably creates a low frequency noise therein. The notable feature of the present implementation includes using the RF signal phase difference as a pseudo-temperature signal. This RF-derived signal is fed into the controller as though it were a traditional thermal sensor input, allowing RF phase shifts to directly influence temperature stabilization through existing TEC infrastructure. The control is preferably entirely electronic and functions within the present closed-loop feedback circuit.

Alternately, temperature sensor may be replaced or supplemented by other sensors. For example, a sensor may be used to detect laser phase frequency shifts by evaluating input and output signals of the RF cavity, inputting the result into a mixer, using the controller software instructions to automatically determine if drift has occurred and adjust a laser, optic, temperature and/or other equipment characteristic accordingly.

The operating principle of this cavity PLL system is to employ RF cavity itself to function as the primary sensor, leveraging the fact that its resonance frequency, fᵣₑₛ, has an extremely high and predictable sensitivity to changes in the cavity material's temperature, T_{cav}. A fixed-frequency RF signal is constantly fed into the RF cavity, and a pickup coil samples the field inside. A dedicated phase detector then measures the instantaneous phase difference, φ_{dif} between the incident signal (monitored via a directional coupler) and the sampled signal from the cavity. If the temperature, T_{cav}, deviates even slightly ΔT_{cav}, the cavity's resonance frequency, fᵣₑₛ, shifts away from the fixed input frequency. This condition, called off-resonance detuning Δfᵣₑₛ, induces a significant and highly sensitive phase deviation Δφ_{dif} in the sampled signal relative to the incident signal, making Δφ_{dif} the system's precise error signal. The voltage output of the phase detector, V_{φ}, which directly corresponds to the phase deviation Δφ_{dif}, is cleverly repurposed as the “pseudo-temperature” scale for the control system. When the cavity is at the desired lock temperature (perfect resonance), V is at a pre-calibrated set-point, Vset. Any deviation in V from Vset is the error signal fed into the temperature controller with PID control. The PID algorithm calculates the necessary power adjustment for the thermal actuators to nullify this error.

These actuators include thermoelectric cooler (“TEC”) plates 307 paired with heat sinks 304 and embedded cooling coils 301. The TEC plates can perform both heating and cooling by simply reversing the electrical current from the power source, as controlled by controller 203. Simultaneously, the embedded cooling coils circulate the chilled fluid for coarse or bulk temperature reduction. PID controller 203 continuously and automatically adjusts the power to the TEC plates and the cooling coils, forcing the temperature, T_{cav}, back towards the target value. As T_{cav} approaches the target, the cavity's resonance frequency, fᵣₑₛ, simultaneously approaches the fixed input frequency, f₀. When fᵣₑₛ≈f₀, the system is near perfect resonance, the phase deviation Δφ_{dif} is minimized, and the pseudo-temperature voltage V returns to the stable lock point. This closed-loop feedback mechanism ensures that the RF cavity is perpetually kept on resonance with the fixed input frequency with a final stability and precision better than sub-50 mK.

More specifically, to examine the performance accomplished by implementing the new cascade loop controller design, the noise spectrum analyses are considered at different levels of feedback controls by the two PID sub-systems. The expected results are given in FIG. 7, first shown with the scenario of open loops. In this free-running scenario, the intrinsic noise spectrum given by the PID-1 sub-loop carries an accumulated RMS noise that rises to 0.013° from 1 Hz to 10⁶ Hz at the line with reference no. 261. Meanwhile, the phase noise detected in the master loop rises to 0.039° RMS from 10⁻⁶ Hz to 10 Hz at the line with reference no. 263. The corresponding noise power spectra are presented in the inset panels, which show temporal correlations with the characteristics of a power-law distribution extended over several decades. Next considered is the synergistic effect from running the two PID control loops simultaneously with the set parameters used in PID-0 optimized for the betterment of overall performance viewed from Δφ₀₃, which necessarily encompasses the increased noise from the active PID-1 sub-loop for reducing the high frequency noises. At this stage of implementation, only the PID-0 parameters are tuned.

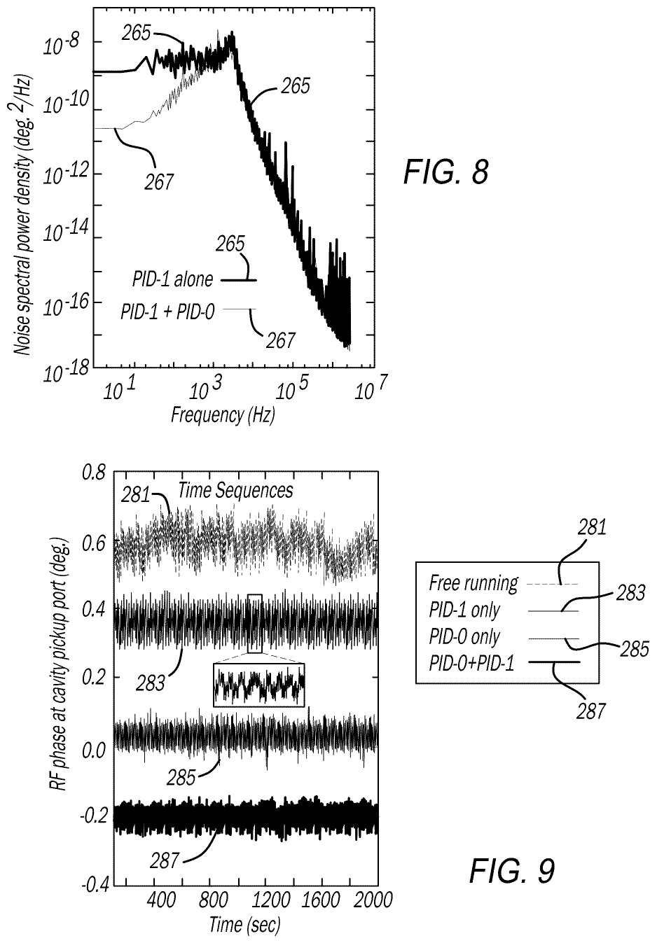

By activating both PID loops, the noise levels drop significantly. For the PID-1 subsystem, the integrated noise reaches the 0.0055° noise floor. In the PID-0 master loop, noises are added in the range above 10 kHz, reaching an overall integrated RMS noise of 0.0089°. By comparing the corresponding noise power spectrum, shown in FIG. 8, it is evident that the improvements are achieved mainly by suppressing the diverging spectral power at lower frequencies; respectively, the feedback action defines a corner frequency fc of 0.5 Hz and 3 kHz for the effective noise suppression in the two loops. The noise below fc is markedly reduced by setting the goal for reducing the integrated noise, however, a slight increase in noise power above fc may be observed as the result of active intervention. FIG. 8 illustrates a noise power spectrum for the present cross-loop interaction over a shared-responsibility range between the two PID control loops in the 10 Hz to 1 kHz range.

The curve with reference no. 265 shows the noise power spectrum from independently running the high-frequency feedback loop, where one can see the noises spectrum levels off at around 1 kHz. However, by turning on the PID-0 feedback control with the goal of reducing the overall integrated noise, the noise spectrum seen at frequency below 1 kHz drops markedly. This synergistic effect can also be viewed from the perspective of PID-0 loop. The expected results are given at different levels of feedback controls, first presented in the time traces in FIG. 9 over the span of 2000 seconds. Here, as the reference, the top trace at reference no. 281 shows the free-running scenario. The second trace at reference no. 283 below gives the results from activating just the PID-1 feedback control, where the noise level is reduced but not significantly. This surprising result is understood by closer examination of the noise fluctuations (inset panel) where a visible telegraph-like noise with switching behavior is shown. The switching frequency of this noise is below 0.1 Hz, thus undetected at PID-1 level. Locally within each plateau, the noise level is significantly lower than the free running case.

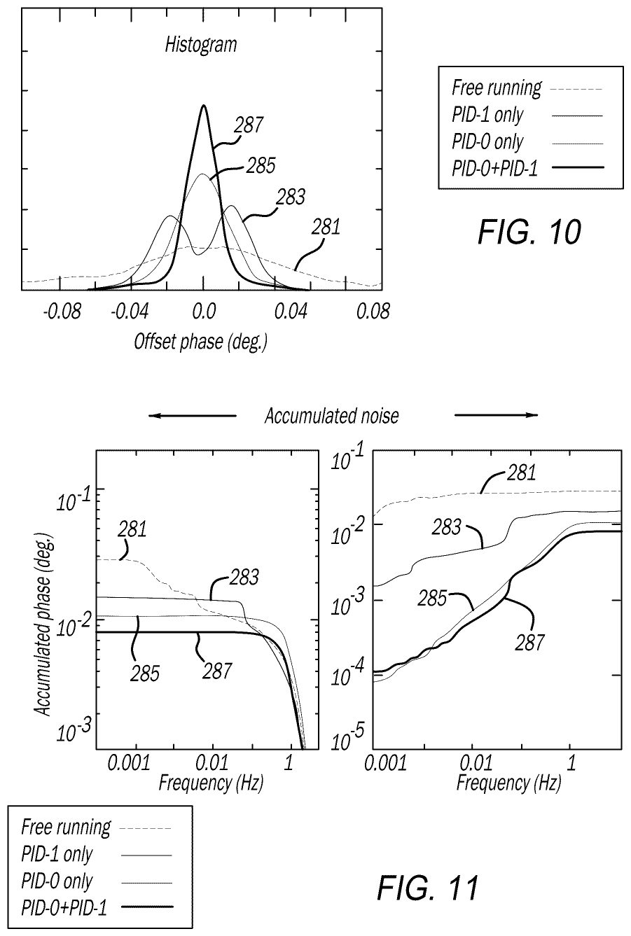

From the histogram analysis, with reference to FIG. 10, these noise features give bi-modal distribution and carry a significant part of the integrated noise. The line at reference no. 285 is by activating only PID-0. In this case, the accumulated RMS noise reaches a level close to 0.01°, better than the previous scenarios, such as those in FIG. 11. But the local noise is higher than the case with just turning on the PID-1 feedback control, albeit no signature of the telegraph noise can be traced here. Therefore, it can be concluded that the presence of the telegraph noise is a spill-over effect from active intervention in the higher frequencies—one that turning on PID-0 feedback control can help remediate. Indeed, by activating the two feedback loops simultaneously, both the local and integrated global noise are reduced.

FIG. 9 illustrates the noise time sequences expected to be obtained by the PID-0 phase detector with increasing levels of PID control. A pronounced source of noises is given at the level of PID-1 feedback control, where the uncompensated noises from PID-1 subsystem overflow into the master loop in telegraph noise-like steps at a relatively low frequency, &0.06 Hz. Next, FIG. 10 represents the phase noise histograms expected from corresponding time sequences in FIG. 10. Then, in FIG. 11, the accumulated RMS noises derived from integrating the noise power spectrum obtained from the time sequences, can be observed. The left sub-panel shows the expected results with integration starting at the high frequency, whereas the right sub-panel gives the expected results with integration starting at the low frequency.

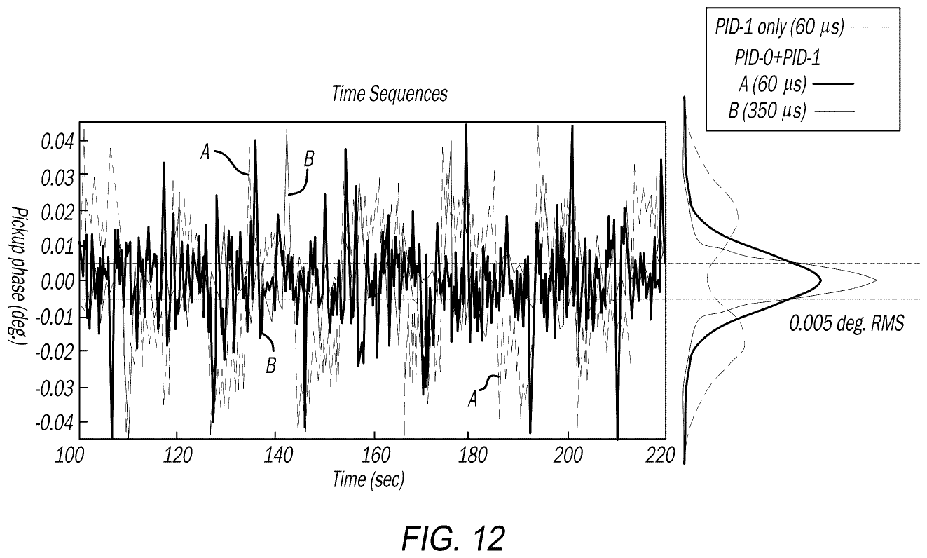

Active intervention of the RF phase stabilities can be tracked by the phase detector at the UEM station. Referring to FIG. 12, the ramification of the noise suppression protocols on expected experimental implementation is considered, where ultrafast diffraction or imaging carried the information frame-by-frame over the acquisition time of seconds. Such identification provides the basis for additional disturbance rejection under the FPGA for every pulse control scheme, leading up to high duty cycle. From this perspective, the RF phase is independently monitored at the UEM column. By comparing the expected results between just activating PID-1 and joint feedback control (PID-0+PID-1), the main improvement made in integrated RMS phase noise comes from reducing the active period of the telegraph noise, and upon averaging their contribution minimizes it to a small pedestal region in the histogram representing the resolution function in the temporal response. Clearly, based on the Gaussian sigma value extracted from the histogram, the precision of the RF system has reached within 0.01° RMS. At this low level of jitters, the sampling error is tested; currently to be sensitive to noise from the higher frequency region for joint feedback control the phase detector integration time is at 60 μs—which is able to pick up the sharp rise of the telegraph noises (and hence correcting the effect in the feedback loop), but the short integration time may introduce a detector noise higher than the noise floor of the device. For this purpose, the acquisition window is raised to 350 μs; see line B. At this acquisition time, the detector is still sensitive to kHz noises and can faithfully detect the residual noise spikes but long enough to reduce the sampling noises. The noise distribution as given in the corresponding histogram gives a much-reduced Gaussian width of 0.0053°. Furthermore, given the confidence that the noise spectrum above 1 kHz is effectively suppressed by the PID-1 feedback control, it is believed that the measurement here does reflect the noise floor from the joint PID control loop.

With real-time recording of the phase noise, the user or controller may manually or automatically adopt a strategy of rejecting the effects from spiky features by setting the acquisition primarily over the low noise regions. Keeping the acquisition time well below the timescale of the noise spikes allows such discrimination. Meanwhile, any residual noise distributed over the acquisition time can be effectively compensated through data processing using the recorded phase as the time stamp to shift the timing. Judicious applications of these strategies could reduce the noise floor for the ultrafast measurements even further.

The present system's sub-50 femtosecond temporal resolution enables better noise suppression and phase locking compared to traditional single-loop PLLs used in earlier RF-based ultrafast electron diffraction systems. The new system achieves temporal precision down to 50 fs through refined phase-space manipulation, significantly outperforming the standard temporal resolution in commercial UEMs. This level of precision enables accurate tracking of ultrafast processes such as coherent phonon dynamics and complex phase transitions in the imaged specimen, which are inaccessible to systems with lower time resolution.

This interactive control structure with high-speed non-IQ sampling allows real-time and automated pulse adjustments, and provides pulse-by-pulse control of high-brightness electron beams, ensuring precise beam delivery even under GHz RF optical lenses operating at high optical duty cycles. This setup allows for digitized beam delivery up to GHz frequencies with real-time disturbance rejection, providing precise control over the dose in raster mode. Accordingly, the present approach thereby offers possibilities for new types of high-speed scanning electron microscopes (SEMs), such as for semiconductor metrology and lithography. The present platform is designed to be robust in non-ideal experimental settings, ensuring reliable operation in both academic and industrial laboratories. Its ability to maintain high performance in such environments improves the deployment flexibility over conventional UEM systems that are more sensitive to environmental noise. FIG. 23 illustrates multi-modality perspective on phase transition dynamics, which shows a comprehensive view of nonequilibrium phase transitions, synthesizing data from UED, DFI, BFI, and inelastically scattered electron transmittance experiments, all performed with identical electron beam settings and a laser fluence of 1.65 mJ/cm² at fᵣₑₚ=1 kHz.

The following optional modifications can be made to further enhance the performance of the present cascade-loop RF controller system:
(A) Implementing optimized PID controller parameters may overcome some drawbacks with the active disturbance rejection control (“ADRC”), such as telegraph noise, when executed in controller at 5 MHz. Furthermore, implementation of both ADRC and PID in the present cascade control loop may be employed.
(B) Increasing clock speed and loop rate can be employed. A higher clock rate runs a higher loop rate, which suppresses the high-frequency noise floor or increases the non-IQ sampling to improve the fidelity for disturbance rejection.
(C) Increasing the loop depth may be performed with additional loop stages, where each layer addresses noise at different frequency ranges. For example, one might assign a designated control range to cover the noisiest range, e.g. in the 1-10 kHz range. This hierarchical noise filtering ensures that any residual jitter or phase error from earlier loops is further reduced, thereby improving both stability and precision.

### EXAMPLE

An exemplary experiment of the present precision-controlled ultrafast electron microscope apparatus on multiple-order coherent phonon dynamics in a 1T-TaSe₂ specimen probed at 50 femtosecond and 10 femtometer scales is set forth as follows. The present ultrafast electron microscope system, having a radio-frequency cavity as a condenser lens in the beam delivery system, is used along with the present cascade loop RF controller system to reduce the RF noise floor. Temporal resolution at 50 femtoseconds in full-width-at-half-maximum and detection sensitivity better than 1% are demonstrated on an imaged exfoliated 1T-TaSe₂ specimen. To benchmark the performance, multiple-order edge-mode coherent phonon excitation is employed as the standard. Phase-space manipulation enables a high temporal resolution and significant visibility to very low dynamical contrast in diffraction signals, moreover, prompts strong support to the working principle for the high-brightness beam delivery in the electron microscope systems.

Stable control through the cascade RF feedback-control circuit, which effectively identifies and suppresses the phase noises to a level that, when transcribed into the beam incoherence envelope, is no more than the contribution expected from the electron bunch emittance floor. At a bunch particle level of 105, the expected stochastic limits are under the scales of 50 fs and 10 nm in ultrafast diffraction and imaging modalities. The beam tests are carried out by operating the microscope in the ultrafast electron crystallography modality on an exfoliated 1T-TaSe₂ thin film. With improved resolution and brightness, a more subtle scattering regime is targeted, involving multiple-order edge-mode phonons coupling to the intervalley scattering, which requires a gentler excitation and is much less explored by a structural probe. At a 5 kHz pump-probe repetition rate, the edge-mode coherent phonon excitation is at 50 fs full-width-at-half-maximum (FWHM) resolution, with a 5 nm coherence length, and sub-1% detection sensitivity.

RF-enabled UEM/UED methodology employs a beam phase-space manipulation protocol, where one can approach a high current efficiency for running the UEM experiments without suffering major loss in spatial and temporal resolutions. Conventionally, the beam delivery in a transmission electron microscope builds on small area emitter where the electrons are extracted to form continuous single-particle stream. The narrow emitters with subsequent condenser demagnetization provide continuous wave TEM the capability to deliver low-emittance and high-coherence beam. However, in the consideration of photoemission with short electron bunches that drives the ultrafast microscope, the probe phase space is necessarily extended by the particle number in the bunch (Nₑ) and the beam brightness depends heavily on the packing density. Normally, in a stochastic source, where the individual particle trajectories may be considered as independent, the associated phase-space area (bunch emittance) would increase linearly with particle number. Due to strong Coulombic interparticle interactions, the beam formation can develop fluid-like behavior. The best delivered beam is one where the bunch emittance grows sub-linearly with increasing Nₑ, leading to an increase of beam brightness—a regime which can be achieved via facilitating and maintaining laminar flow from the source to the specimen target. Specifically, phase-space manipulation is used to reverse the velocity chirp effect derived from particle streams in order to form coherent illumination from space-charge-dominated beam. This, in turn, reduces the electron footprint but not the emittance size.

The phase-space manipulation is carried out through the joint application of magnetic (transverse) condenser and the new RF-cavity-based longitudinal condenser, and appropriate phase-space slicing the cross-dimensional effect. The high-intensity electron bunch is generated at a Pierce-gun photocathode via front-illumination by 266 nm drive laser pulses up to the virtual cathode limit. The flat cathode geometry, and its proximity-coupling to a source condenser lens, facilitate laminar flow emission just below the virtual cathode effect. Furthermore, the beam is fed into the condenser system of the UEM column, where an RF cavity is specifically inserted between magnetic lenses and serves as a new optical element to condense the bunch profile longitudinally. Meanwhile, the magnetic condenser and objective lenses demagnify the beam transversely. With two types of condensers acting together, a pancake beam is typically formed through different lens settings. Just prior to illumination, a variable-size aperture array is employed to slice the emittance (and particle number) as required.

It is desired to deliver the bunch in a proper aspect ratio that best projects the particle stream into the prioritized resolution window. By running the RF-cavity field to reverse the longitudinal velocity chirp, the RF condenser refocuses the pulse to a smaller footprint along with positional or momentum direction to create a focused or temporally coherent pulse at the specimen plane. Similar action from the magnetic condenser sets the illumination conditions as either spatially more focused (for imaging) or coherent (for diffraction). However, the applications of RF and magnetic condensers are not entirely independent since the longitudinally tightened beam, tends to expand transversely due to internal space-charge forces.

The basic physics behind these builds on the strong inter-particle correlation mediated through Coulombic interaction, which tends to develop bi-directional flows: the thermal particles with higher kinetic energy flow to the exterior whereas the laminar flow develops from condensing the low-entropy particles at the core region. On the basis of this bi-directional flow concept, a high-brightness regime for operating the UEM beamline can be conceived. This strategy, of applying an appropriately sized condenser aperture near the specimen, targets the high-brightness core of the particle streams. At this stage, the bi-directional flow has fully developed and the slicing along the transverse axis simultaneously removes longitudinally divergent particle streams in the circumference region more than the core. This laminar-flow high-brightness strategy results in a local boost in brightness for the beam delivered to the specimen. Such phase-space manipulation of high-intensity electron bunches becomes the foundation for operating the present type of RF-enabled UEM system with a high current efficiency.

Electron focusing in the present exemplary UEM system is next addressed. The coupling between the phase space is used to understand the TEM optical manipulation with magnetic and RF condenser lenses, which are considered as a stochastically filled area or emittance, to the optical transfer function modelled in the context of objective aberration function. To illustrate the theoretical principles, the contributions from a noisy RF source are first ignored. The effects from a finite-sized electron bunch phase space to the resolution function of the TEM are traced. In this phase-space-based picture, the beam incoherent illumination causes information loss and degrades the resolution which can be modelled through the spatial and temporal incoherence envelopes: E_{S}(k) and E_{T}(k), expressed in the Fourier spatial frequency k. As part of the (objective) lens transfer function⁴⁰, these incoherence envelopes restrict the information at high k, given by

$$t ( k ) = {E}_{s} ( k ) {E}_{T} ( k ) {e}^{{i}_{χ} ( k )} , \qquad ( 1 )$$

where χ(k) gives the phase factor of the distorted wavefront. The envelope functions are given by:

$$\begin{matrix}{E}_{s} ( k ) = exp \{ - {[ {πσ}_{s} ( {C}_{s} {λ}^{2} {k}^{3} ) ]}^{2} \} , \\ {E}_{T} ( k ) = exp \{ - {0.5 [ {πσ}_{T} ( {C}_{c} λ {k}^{2} ) ]}^{2} \} ,\end{matrix} \qquad ( 2 )$$

where λ is the electron de Broglie wavelength. The direct impact from the incoherence phase-space envelope is seen in the coupling between exponent as, the root-mean-square (RMS) of the beam convergence angle, and the spherical aberration coefficient C_{S}, which results in an expanded cone of incoherent illumination. Namely, a large transverse emittance size εₓ, which propagates into a large transverse extremum size through focusability, is expected to limit the spatial resolution (R₀) or the coherence length (X_{c}) from the bunch illumination.

Meanwhile, taking temporal incoherence envelope into consideration, σ_{T} is defined by,

$${σ}_{T} = {[ {( \frac{{σ}_{E}}{{E}_{0}} )}^{2} + {( 2 \frac{{σ}_{I}}{{I}_{0}} )}^{2} ]}^{1 / 2} , \qquad ( 3 )$$

with σ_{E} and σ_{I} the RMS deviation of the beam energy (E₀) and objective current (I₀), couples to the lens chromatic aberration coefficient C_{c}. The expanded σ_{T} limits the spatial resolution due to the cross-dimensional effect; namely beam temporal incoherence causes an imprecision in spatial focusing. It is easy to see that the instability of the RF optics will couple to the lens optics through an increase in σ_{T}. Hence, an imprecise RF lens not only cause a loss in temporal resolution, but also impacts the spatial resolution directly in an UEM. The resolution loss is given by the complementarity (Fourier-pair) relation between the resolution function R(r) and the transfer function t(k)¹⁹:

$$R ( r ) = FFT t ( k ) . \qquad ( 4 )$$

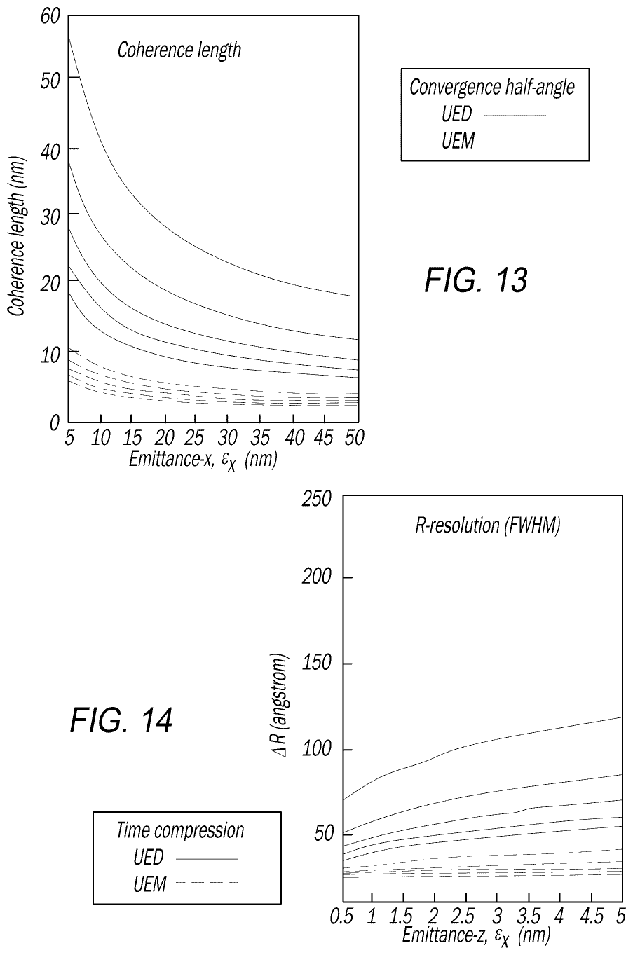

FIGS. 13-16 present the results modelled for the UEM and UED modalities where the optical tunings of the transverse and longitudinal phase-space structures are carried out through the magnetic and RF condensers, measured in terms of the convergence half angle and the compressed pulse width Δt. For evaluating the effect on the focusing property, the results are given for different transverse and longitudinal emittances.

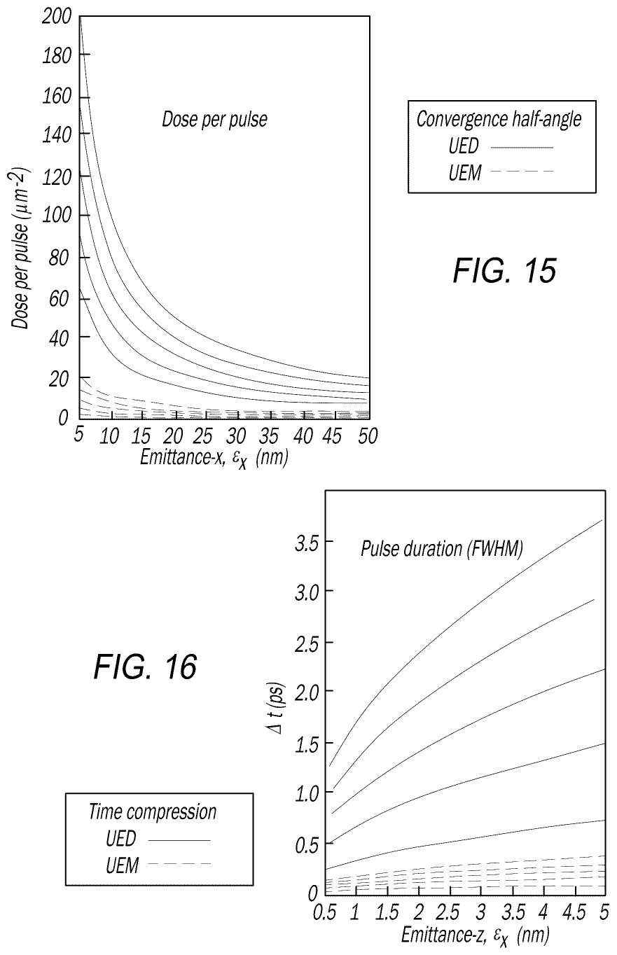

FIGS. 13 and 15 show optical tuning in a transverse direction while FIGS. 14 and 16 show optical tuning in a longitudinal direction, where UEM and UED performance occurs from tuning the condenser system. More specifically, FIGS. 13 and 15 give the performance in the coherence length and electron dose under the tuning of the beam convergence half angle, a control parameter set by the magnetic condenser current and aperture size. Furthermore, FIGS. 14 and 16 give the performance in the imaging and time resolution under the tuning of the RF condenser.

The model considers the beam energy of 60 keV with Nₑ=10⁵. The UED and UEM categories are classified based on the tuning ranges. For UEM, the convergence half angle from 0.6 to 3.5 mrad is varied, subject to the demagnification of the beam by the condensers as a virtual source at the front focal distance of the objective prefield. Moreover, the angle is subject to the value of εₓ, the condenser settings, and the prefield focal distance (1.4 mm). For UED, this angle is 0.1 to 1.1 mrad. Alternatively, in the tuning of the RF condenser, the longitudinal focusing Δt is set for UEM from 250 to 750 fs (FWHM) at the low emittance, but nominally this figure is increased by the square root of ε_{z} to simulate spatial resolution. For UED, the setting for Δt is smaller, starting from 25 to 75 fs at low ε_{z}. The microscope resolution function from the derivation of ΔR is calculated using the lens aberration coefficients C_{S}=1 mm and C_{C}=1.9 mm.

Here, the categorization of modality is based on the starting values of the tunning parameters. As the tuning parameters are varied, the performance in ultrafast diffraction and imaging may be prioritized; however, regimes, where UED and UEM experiments are carried out at similar optical settings can be approached, namely a joint multi-modal scheme under the same beam illumination condition may be developed, but with some compromises in resolution from each channel. For operating in the imaging modality, the primary goal is set to optimize the spatial resolution ΔR. In this case, a larger convergence half-angle is set to promote the dose over the coherence length and a high temporal coherence is preferred over the temporal resolution to reach sub-10 nm spatial resolution.

In case of ultrafast diffraction, the system is prioritized for higher X_{c} and short pulse-width. Consequently, the dose and direct-space resolution may suffer. The divergent trends from these simulations over the emittance provides the guidance, based off the delivery of performance in UED and UEM modalities, to set bounds on the size of emittance. While the assignments give only the order-magnitude precision on the beam emittance, it is instructive to point out the assigned characteristic emittance is consistent with the source emittance given by the multi-level fast multipole method simulation optimized for the laminar flow regime.

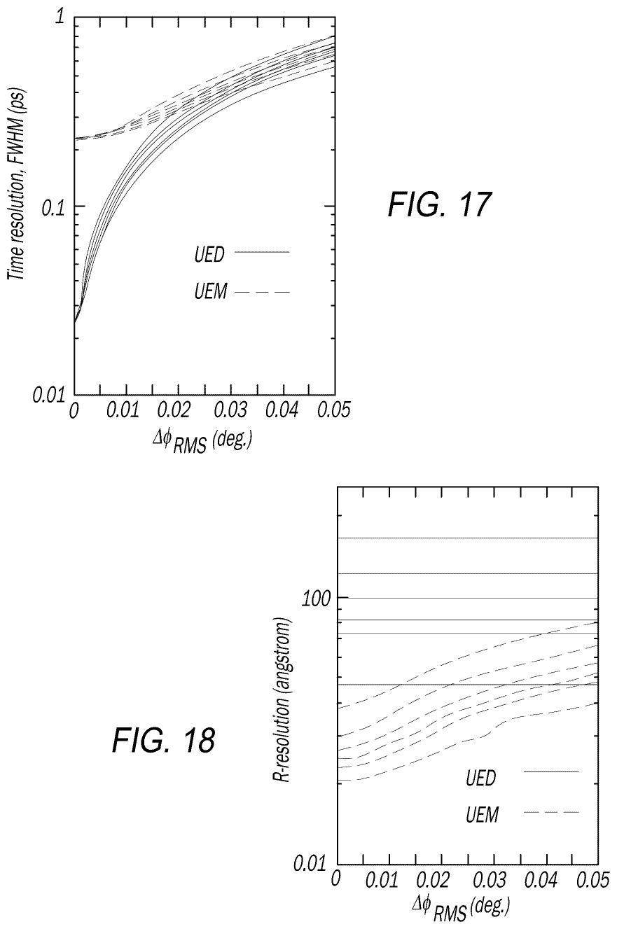

The graphs of FIGS. 17 and 18 depict the impacts from the RF instabilities on the temporal and spatial resolutions. FIG. 17 illustrates the temporal resolution for UEM and UED modalities modelled for the nominal values of εₓ=10 nm and ε_{z}=1 nm for Nₑ=10⁵. The results are calculated for the beam energy varied from 40 to 120 keV and 200 keV. Moreover, FIG. 18 presents the corresponding changes in the imaging resolution. The different RF optical settings for UED and UEM reflects different phase-space aspect ratio prioritized for either imaging or ultrafast diffraction. For imaging, the energy spread is 0.3 eV to allow for sub-10 nm imaging resolution, while for UED, it increases to 250 eV to give a better temporal resolution set by the emittance floor.

The effects on the resolution from a noisy RF source feeding the RF-cavity longitudinal lens are now traced. To understand this effect on the performance, the RF phase instability Δφ is related to an increase of temporal incoherence envelope given by the beam velocity spread:

$$\frac{Δ {v}_{0}}{{v}_{0}} = - η \frac{{γ}^{2}}{1 + {γ}^{2} {β}^{2}} Δϕ , \qquad ( 5 )$$

where γ, β are the relativistic factors, and η is the RF focusing parameter set by the cavity RF resonance field ε(t)=ε₀ sin(2πf₀t+φ) at

$$η = \frac{e {ε}_{0}}{{γ}^{3} π {f}_{0} {mv}_{0}} sin ( \frac{π {f}_{0} d}{{v}_{0}} ) cos ϕ \qquad ( 6 )$$

where ν₀, d, and ε₀ are the bunch velocity, the gap size, and electric field amplitude of the cavity. Specifically, the values of η to reach the two extrema shown in FIG. 14 is set by the focal distance Lₗₑₙₛ₋ₛₐₘₚₗₑ, with

$${η}_{E} = \frac{{a}_{0}}{2 π {f}_{0}} and {η}_{t} = \frac{{a}_{0} + {v}_{0} / {L}_{lens - sample}}{2 π {f}_{0}}$$

at bunch zero-crossing (φ=0 upon arrival at RF gap, see FIG. 14), where a₀ is the bunch phase-space chirp, respectively for spectral and temporal compression. The corresponding arrival time jitter influencing the deliverable temporal resolution is given by

$$Δ {t}_{arr} = \frac{η {L}_{lens - specimen} {γ}^{2}}{{v}_{0} ( 1 + {γ}^{2} {β}^{2} )} Δϕ . \qquad ( 7 )$$

Based on nominal emittance deduced for Nₑ=10⁵, and the RF lens settings where f₀=1.013 GHz, d=2.1 cm, the incoherence envelops are calculated following Equations (5)-(7) at the respective extrema for the UED and UEM experiments. The additional temporal incoherence from the RF cavity σ_{φ} is convoluted into the overall incoherence width by

$${σ}_{T} = \sqrt{{σ}_{ϕ}^{2} + {σ}_{E}^{2}} ,$$

from which the spatial resolution is determined. The results calculated for different beam energies are presented in FIGS. 17 and 18 where the impact on the temporal resolution is largest in the ultrafast diffraction. Based on the simulation, it is possible to compress the bunch down to 22 fs (FWHM) which only weakly depends on the beam energy. This weak energy dependence can be seen in the time-to-phase ratio,

$${k}_{t ϕ} = \frac{η {L}_{lens - sample} {η}^{2}}{{v}_{0} ( 1 + {γ}^{2} {β}^{2} )} .$$

With L_{lens-specimen}≈0.4 m in our setups, k_{tφ} of 4 to 4.5 is estimated for beam energy from 40 keV to 100 keV. Meanwhile, the impact on the ultrafast imaging lies in the spatial resolution. Irrespectively, the high sensitivity to the RF noise at the fs-nm scale measurements is quite noticeable, which highlights the importance for further improving the phase stability of the RF system. For testing the emittance floor based on k_{tφ} given in both scenarios, an RMS noise close to the level of 0.005° is desired.

While the core optical technologies combining magnetic and RF condense lenses promise to deliver a bright beam with sub-100 fs temporal resolution (e.g., the simulation presented in FIGS. 17 and 18 promises 22 fs FWHM at the specimen plane), translating such short bunch delivery to the performance prefers a high stability and precision on the control system. For the UEM systems, the synchronization between the laser pump and the RF system seeding the RF cavity is achieved through a phased locked circuit. This exemplary circuit includes a fast-rectifying photodiode that converts the light pulse signal from the laser oscillator into a frequency comb up to multi-GHz. The resonance frequency f₀ of the RF-cavity optics is locked on to the frequency comb at an integer harmonic at 1.013 GHz. As the signals running from the laser front end to the UEM cavity port is over an extensive distance, the success of the RF phased-locked circuit depends on identifying the spurious noise sources and their removal, which often involves proportional-integral-derivative (“PID”) control loops over the appropriate time scales of the experiments.

The previously discussed two-level, cascading PID system for RF phase control and noise suppression is used. Specifically, a higher frequency PID-1 inner loop with a digital phase-locked loop is proximity-coupled to the UEM column. It deals with the local phase noise Δφ₁₃ measured between the signal fed into the low-level RF controller and the signal at the cavity pickup port. A feature of this LLRF controller is the System-on-Chip (“SoC”) field programmable gate array (“FPGA”) design, fast data converters that allows direct sampling at 1.013 GHz and PLL chips with good phase noise performance up to 100 kHz that generates clocks for data converters and FPGA. Thus, the LLRF controller can easily suppress any local phase noise within the cavity bandwidth ≈0.1 MHz.

Meanwhile, PID-0 is the master feedback-loop overseeing the entire length of the RF circuit. It compensates the phase difference, Δφ₃, measured between the laser frontend and the RF pickup port; the output for the phase compensation is fed into the PID-1 subsystem. The PID-0 feedback-control employs a 4 MHz digitizer with averaging over 1 k samples to reach sufficient phase detection precision to run the PID. The sub-millisecond detection time allows the system to detect noise spectrum beyond 1 kHz, yet the system operates at 10 Hz to give the overall phase stability it needs for longer term operation.

By activating both PID loops, the noise levels drop significantly. For the PID-1 subsystem, the integrated noise reaches the 0.0055° noise floor. In the PID-0 master loop, noises are added in the range above 10 kHz, reaching an overall integrated RMS noise of 0.0089°. By comparing the corresponding noise power spectrum, it is evident that the improvements are achieved mainly by suppressing the diverging spectral power at lower frequencies; respectively, the feedback action defines a corner frequency fc of 0.5 Hz and 3 kHz for the effective noise suppression in the two loops. By setting the goal for reducing the integrated noise, the noise below fc is markedly reduced; however, a slight increase in noise power above fc may be observed as the result of active intervention.

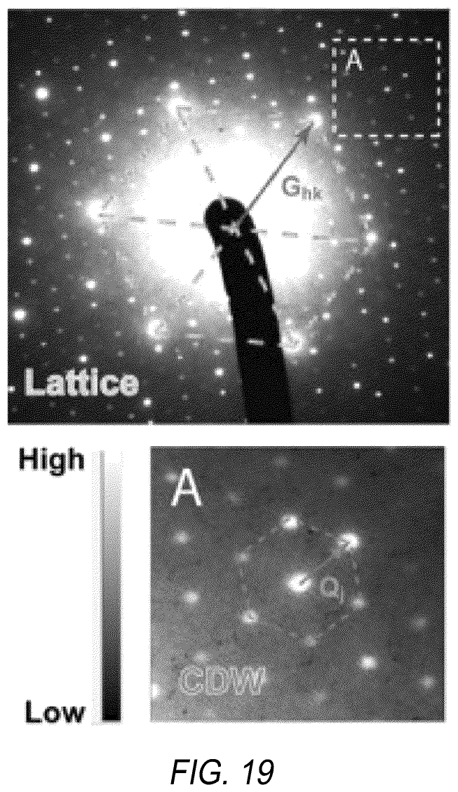

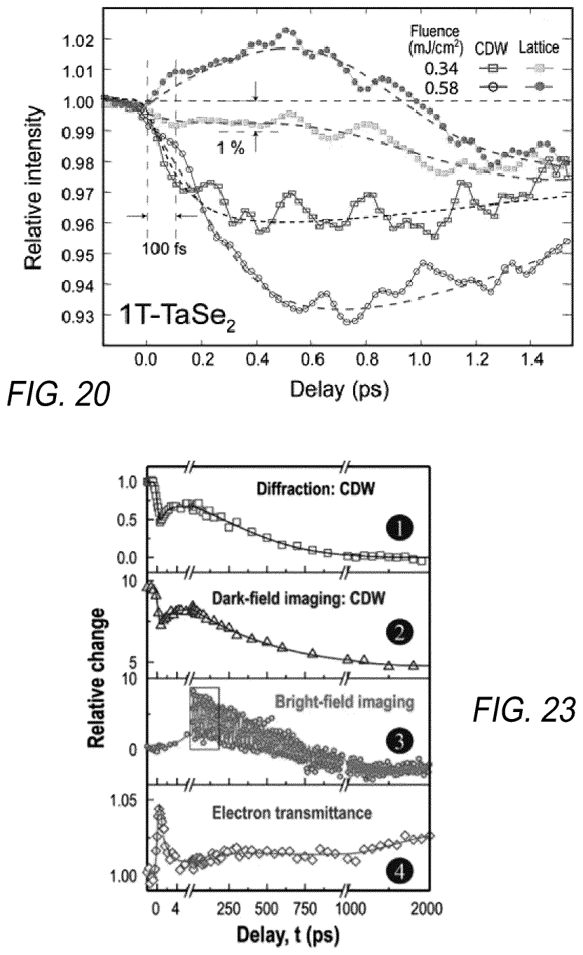

Performance validation is considered with multiple-order coherent phonon dynamics in 1T-TaSe₂. FIG. 19 shows a diffraction pattern from the exfoliated 1T-TaSe₂ sample. The dashed lines outline the corresponding triangular lattice and CDW supercells periodicities. FIG. 20 graphs intensity modulations registering the coherent phonon dynamics and the incoherent channels including the thermal phonon signatures and the density-wave state evolutions; see text for details. The coherent multiple-order nonlinear phonon excitation involving zone-edge (K) acoustic phonon in periodic high and low intensity modulation is visible in the low fluence data set.

The 1T-TaSe₂ specimen is prepared through tape-exfoliation to ≈40 nm thickness over ≈25 μm in lateral size and pumped with 30 fs near-IR (800 nm) laser pulses at 45-degree incidence under the vacuum. The pump-probe UED experiments use a bunch charge limited to 105 to confine the emittance in the nm scale to approach the required sub-100 fs temporal resolution. The scattering data integration is carried out at 5 kHz repetition rate over an 8-sec integration time to gather more than 10⁷ electrons in the relevant Bragg scattering. Accordingly, the overall sensitivity is expected to reach sub-1% over the intensity modulation to resolve the LA phonon dynamics expected at smaller than picometer scale.

The expected results are given in FIG. 20, obtained by employing the ultrafast crystallography modality. 6-cycle-averaged diffraction patterns are shown, where the TaSe₂ triangular lattice and CDW superlattice formation are identified by the sharp scattering features resulting in corresponding structure factors S_{G}_{ₕₖ}(s) and S_{Q}_{ⱼ}(s) located by the wave-vectors Gₕₖ and Qⱼ in reciprocal space (s). Differential scattering intensities are integrated over the S_{G}_{ₕₖ}(s) and S_{Q}_{ⱼ}(s), in order to investigate the dynamics. The changes are normalized to the ground-state levels obtained at delays before the pump-probe zero-of-time. With this self-normalizing scheme, multi-THz signatures of coherent phonon dynamics modulating the integrated intensity of the two structure factors can be disentangled well below 1% level.

To better decipher the coherent signatures and the related dynamics resulted from the perturbative changes in the broken-symmetry order as well as coupling to the lattice phonon bath, properly assigning the different evolution channels to different co-factors in the structure factors is used. The structure factor associated with the broken-symmetry CDW order, S_{Q}_{ⱼ}(s), is given in the basis of the unmodified lattice form factor f_{L}:

$$F ( s ) = \int {dre}^{- is \cdot r} {\sum }_{L} {f}_{L} δ ( r - L - {u}_{L} ( t ) ) , \qquad ( 8 )$$

where L denotes the position of the undistorted lattice. The dynamical evolution shown in lattice and superlattice peaks are given by lattice displacement field u_{L}=u_{q}+u₇, depicted by two different types of lattice waves: the lattice phonons (u_{q}) or collective field modes of the broken-symmetry order (u_{η}) with momentum wavevector {q} and {k} given by q=s−Gₕₖ and k=s−Gₕₖ−Qⱼ, referencing to the central Bragg reflection Gₕₖ.

In this independent mode picture, the carrier wave effects are understood, unrelated to the broken-symmetry collective order changes. Such effects underscoring the coherent u_{q}(t) dynamics are given by the common co-factors in S_{G}_{ₕₖ} and S_{Q}_{ⱼ}. Indeed, the appearance of the phase locking in the observed S_{G}_{ₕₖ}(s, t) and S_{Q}_{ⱼ}(s, t) reflects this. To better evaluate the lattice displacement and frequency responses, the non-oscillating transient (in dashed line) is first extracted to examine the coherent modes. The oscillating signatures can be isolated as a superposition of two LA mode frequencies at 3.1 and 6.2 THz from direct Fourier analysis as well as model reconstruction. The LA mode amplitude is determined based on the intensity modulation. The ≈0.5% amplitude change gives the coherent phonon amplitude at the level of 5×10⁻⁴ Å. Meanwhile, incoherent coupling to lattice phonon bath is presented in the u_{q}-channel given as the Debye-Waller factor (DWF) from incoherent summing. The relevant dynamics is given as the ‘thermal’ RMS amplitude u_{T} that contributes as an exponential decay given by momentum-dependence

$${e}^{- {\vert {G}_{hk} \vert}^{2} {u}_{T}^{2}} .$$

This direct coupling to the phonon bath could be retrieved from the sub-ps drop in the baseline levels both in S_{G}_{ₕₖ}(s, t) and S_{Q}_{ⱼ}(s, t). Accordingly, an RMS incoherent amplitude u_{T}≈2×10⁻⁴ Λ is deduced from the decays at different moments.

Next considered is the corresponding evolution of the density wave state. Even in the gentle excitation regime, it is expected that the direct promotion of carries condensed within the CDW collective to the excited orbitals, shall weaken the strength of CDW. From the symmetry-breaking perspective, this effect, involving u_{η}, manifests in the counteracting movements from S_{Q}_{ⱼ} (a reduction) and S_{G}_{ₕₖ} (an increase). The S_{Q}_{ⱼ}(s, t) intensity change reflects the order parameter suppression, by 3×10⁻³ Å, to occur on the same sub-100 fs timescales. The rapid, collective response is an indication that an alternate displacive effect is already at play, even at a low excitation level. This is checked by doubling the excitation fluence. As a result, the nonlinear quantum scattering signatures are indeed nearly washed out and, in its place, a broader range of phonon excitation is visible.

Upon applying IR pulse excitation just above the gap energy (0.6 eV), a transient nonequilibrium valence-band electronic manifold is shown to promptly settle in, with a transient electronic temperature up to 0.4 eV. Under this deformation stress a reduction of CDW energy gap, by an amount of up to ≈22%, occurs in & 0.3 ps, followed by a short recovery to ground state on just 1 ps timescale. Meanwhile, a separate UED investigation focused on the phase transition and excited the system with a significantly higher intensity, which is in a different regime and find charge transport across the stacking direction, establishing a 3D response associated with commensurate-to-incommensurate transition.

Basing off the transient dynamics, the subject of evaluating the RF-optics-incorporated beamline performance is hereinafter discussed. First, the dose is determined to be 3 e/μm² and a coherence length of 5 nm based off the “atomic grating” approach adopted previously in carrying out the electron bunch characterization. These give a transverse emittance εₓ≈5.7 nm, which largely is aligned with the previous results. The increased electron dose leads to a better resolution in discerning the structure dynamics. To evaluate the corresponding resolution from the signal floor in the diffraction contrast, the nominal noise level σ_{Q}≈0.1% is taken over the intensity of S_{Q}, providing the distinction of the multiple-order oscillations. The amplitude scale corresponding to this minimum distinguishing scale can be estimated by the Overhauser's formula for CDW structure factor⁶¹ S_{Q}˜|J₁(Qα)|². Since the corresponding CDW amplitude a ≈0.2 Å in TaSe₂, the noise floor gives the minimum detectable amplitude at the level of 10 femtometer. For the temporal resolution, it may be evident the RF compression has reached the sub-100 fs resolution judging from the initial response time in the UED signatures.

As it depends on the knowledge of the physical initial decay, a more independent evaluation could be based on the visibility for discerning the well-established features at higher frequencies. Following the convolution principle, a bound for the response time is given using σ_{c}/\sqrt{2} in RMS, where the specific σ_{c} is determined from carrying out convolution of the data with a gaussian sigma σ_{c}, until the high harmonic transient signatures become indistinguishable. Through this method, a temporal resolution of ≈50 fs (FWHM) is used based on the minimum level convolution at ≈30 fs RMS to smear out the high harmonic signatures.

### Exemplary Performance Parameters:

Integration of Optical and Electron Modalities: Seamlessly align optical pump-probe setups with electron microscopy to enable simultaneous measurements and analysis.
Synchronization Precision: Maintain <10 fs synchronization between GHz and kHz laser systems to support pump-probe experiments.
Resolution in Dual Modalities:
   Electron Microscopy Resolution: Target 10 fs and 1 nm resolution in UTEM for high spatial and temporal precision.
   Optical Resolution: Achieve diffraction-limited optical resolution to support complementary optical measurements with the electron modalities.
Pump-Probe Delay Flexibility: Provide flexible pump-probe delay stages, allowing users to adjust timing to capture a range of transient events with precision.

### Scientific Preferences:

Laser-to-Laser Synchronization: Achieve <10 fs synchronization precision between optical spectroscopy and electron imaging systems to enable accurate time-resolved correlative measurements.
Beam Stabilization: Implement beam stabilizers with <0.5 μm pointing stability at specimen and photocathode to maintain alignment between modalities.

A summary of exemplary performance parameters and scientific requirements includes:
Scan Rate: Achieve GHz-level control over each beam in a multi-beam SEM configuration, enabling rapid image acquisition for large surface areas.
Spatial Resolution: Target 10 nm resolution to meet precision standards for semiconductor and material inspections.
Field of View: Configure scanning to cover up to 100 micrometers (μm), allowing high-throughput scanning of large areas without sacrificing resolution.
Beam Intensity and Uniformity:
   Intensity Stability: Maintain <1% intensity variation across the scan area to ensure uniformity.
   Beam Profile: Use pancake or multi-beam configurations to increase throughput of the electron bunch, without sacrificing resolution.

In a preferred embodiment, the present microscopy system and method operates the drive laser in the GHz regime and produces high-brightness imaging with electron-beam brightness of at least 3.67×10⁷ A·cm⁻²sr⁻¹, an electron-bunch throughput of at least 1.6 μA, and a temporal resolution of less than 50 femtoseconds. Furthermore, a different embodiment, operating the drive laser in a MHz regime, yields proportionally scaled performance, including reduced brightness and throughput that remain linearly proportional to the operating repetition rate while preserving femtosecond-scale temporal resolution. Moreover, another embodiment employs a method for ultrafast electron imaging including generating an electron probe using a laser-driven photocathode operated at a repetition rate in the MHz to GHz range, and delivering the electron probe to a specimen to obtain high-brightness of at least 3.67×10⁷ A·cm⁻²sr⁻¹, an electron-bunch throughput of at least 1.6 μA, and femtosecond-scale temporal-resolution imaging (for example, less than 50 fs), wherein the brightness and beam current scale substantially linearly with the laser repetition rate.

Another optional configuration may employ integration of artificial intelligence (“AI”) software instructions for microscopy system optimization, such as being incorporated into the present high-speed electronics for beam control and stability. Machine learning (“ML”) algorithms may automatically optimize beam parameters (such as energy, position and/or focus) and provide real-time feedback for dynamic stability. Reinforcement learning models will adaptively tune beam optics to maintain quality, reducing the need for manual intervention. One element is the GHz-level loop rate for every-pulse control through using the field-programmable gate array (FPGA) platform. This high-speed architecture, coupled with FPGA-compatible ML-feedback loop, will automatically adjust system components in real time, improving beam stability and reducing downtime, thereby ultimately enhancing the consistency of high-throughput operations.

The present apparatus integration of optical spectroscopy and electron imaging modalities advantageously provides multi-dimensional insights into complex systems, enabling cross-disciplinary applications in materials science, biology and nanotechnology. Synchronization between kHz and GHz laser systems enables multiplexed time-resolved measurements, with the kHz laser serving as the pump and synchronized GHz-rate pulse sequences generating photoelectron and optical probe pulses for dual-probe analysis. The GHz-level FPGA controller facilitates correlative measurements, managing optical signals across all timescales and employing beam blanking to isolate ultrafast electron probe data synchronized to the kHz clock. For longer timescales, optical signals are organized into time-sequenced datasets, while targeted beam blanking addresses limitations in camera detector speeds. This integrated approach beneficially allows comprehensive studies of phase transitions and dynamical control mechanisms, spanning sub-100 fs ultrafast processes to longer relaxational dynamics at the ns-to-ms scale.

The present apparatus further addresses the need for tools capable of probing radiation-sensitive systems like biological specimens, requiring lower doses and high-speed scanning to prevent sample degradation. High-throughput multibeam electron microscopy integrates speed and reduced dose rates, enabling the capture of delicate biological structures and radiation-prone semiconductor materials. Additionally, ultrafast imaging of quantum materials with atomic resolution allows researchers to explore fundamental phenomena such as superconductivity, charge density waves, and topological states, which often manifest only under specific transient conditions. By integrating high brightness and throughput, and achieving high spatial-temporal resolution, this system represents a breakthrough in electron microscopy. It paves the way for transformative advancements in diverse fields, including electronics, catalysis, condensed matter physics, and biomedical sciences. By harnessing the self-organization of high-density photoelectron pulses, the present apparatus has achieved a new approach to electron emission that matches field emission gun (“FEG”) brightness while allowing high-throughput performance. This advancement is made possible through the use of large-area photo-emitters and ultrashort laser pulses, leading to simultaneous boosts in both brightness and emission rates. The modular design of this ultrashort, digitized beam delivery system enables scalable implementation, allowing for high-resolution and high-speed applications in a single platform.

Notable impacts include atomic-scale imaging with enhanced field-of-view capabilities, enabling comprehensive exploration of phase changes, coherent phonon dynamics, and defect dynamics in quantum materials. The enhanced beam throughput allows SEM systems to operate at GHz-level repetition rates, ideal for semiconductor inspection, interface analysis, and studies on radiation-sensitive biological samples. This high-speed beam capability also supports dynamic contrast imaging, allowing real-time visualization of material transformations and defects for materials research.

It is alternately envisioned that the control system, software and method of operation of the present microscope system presented herein, may be applicable to non-RF ultrafast electron microscopes. Nevertheless, the present control system, software and method of operation are best suited for an RF ultrafast electron microscope.

While various embodiments have been disclosed, other variations may be employed. In an optional configuration, the present RF cavity temperature control system, circuit and software can be employed with other types of electron microscopes. Additional or alternate laser or electron beam optics and electrodes can be employed although some advantages may not be realized. For example, FPGA may be replaced by a pre-fabricated and pre-programmed, application-specific integrated circuit “ASIC”) chip (both the FPGA and ASIC chips being programmable logic device integrated circuits with logic gates), although some of the preferred benefits (such as cost and programming flexibility) may not be achieved. Furthermore, additional or alternate software and control steps, and/or electrical circuitry, may be provided in the present system but all of the present advantages may not be obtained. All of the features of the disclosed embodiments may be mixed and matched with each other and features of one embodiment may be used with the other embodiments. It is intended by the following claims to cover these and any other departures from the disclosed embodiments which fall within the true spirit of this invention.

The invention claimed is:

1. A method of using an electron microscope, the method comprising:
(a) emitting a laser pulse to a photocathode;
(b) emitting an electron bunch from the photocathode to a radio frequency cavity;
(c) emitting the electron bunch from the radio frequency cavity to a specimen;
(d) detecting an image from the specimen;
(e) suppressing low-frequency disturbances in the electron bunch;
(f) controlling high-frequency radio frequency jitters to reduce noise in the electron bunch;
(g) overlapping the suppressing step (e) and the controlling step (f) in a frequency region to cancel undesired electrical or photonic noise in all frequencies; and
(h) coordinating laser-to-laser and laser-to-radio frequency synchronization.

2. The method of claim 1, further comprising operating a drive laser in the GHz regime produces high-brightness imaging with electron-beam brightness of at least 3.67×10⁷ A·cm⁻²sr⁻¹, an electron-bunch throughput of at least 1.6 μA, and a temporal resolution of less than 50 femtoseconds.

3. The method of claim 1, wherein operating a drive laser in a MHz regime yields proportionally scaled performance, including reduced brightness and throughput that remain linearly proportional to an operating repetition rate while preserving femtosecond-scale temporal resolution.

4. The method of claim 1, further comprising:
using a sequence of multiples of the laser pulse, triggered by a MHz or GHz laser;
tuning the sequence with the radio frequency cavity acting as a lens; and
obtaining simultaneous measurements with both photon and electron probes in order to observe dynamic events in the specimen initiated by a pump laser pulse.

5. The method of claim 1, further comprising a programmable controller automatically synchronizing dual-probe timing in less than 50 femtosecond precision using optical delay stages and causing digital delay sequences at multi-GHz frequencies.

6. The method of claim 1, further comprising using a programmable logic device integrated circuit, with logic gates, paired with a data converter that interfaces directly with the radio frequency cavity to suppress local phase noise within a bandwidth of the radio frequency cavity.

7. The method of claim 1, further comprising electrical circuitry using at least two phase-locked loops of which a digital and higher speed loop is used for the suppressing step, and an analog and lower speed loop is used for the controlling step, wherein the digital loop serves as a master feedback loop overseeing an entire radio frequency circuit and feeds phase corrections into the analog loop.

8. The method of claim 1, further comprising:
constantly feeding a fixed radio frequency signal into the radio frequency cavity, when the electron microscope is operating;
sampling a radio frequency field inside the radio frequency cavity;
measuring an instantaneous phase difference between an incident signal, monitored by a directional coupler, and the sampled signal from the radio frequency cavity, with a phase detector;
shifting a resonance frequency of the radio frequency cavity when a temperature of the radio frequency cavity varies;
detecting a voltage output change from the phase detector, which corresponds to the phase difference, when the temperature varies;
automatically comparing the detected voltage output change to a desired value; and
automatically adjusting a thermal actuator in response to the comparison, which automatically changes heating or cooling of the radio frequency cavity.

9. A method of using an electron microscope, the method comprising:
(a) emitting a laser output to a photogun;
(b) sending electrons from the photogun to a radio frequency cavity;
(c) sending the electron bunch from the radio frequency cavity to a specimen;
(d) obtaining an image from the specimen;
(e) suppressing low-frequency disturbances in the electrons; and
(f) deterring high-frequency radio frequency jitters to reduce noise in the electrons.

10. The method of claim 9, further comprising obtaining high-brightness imaging of at least 3.67×10⁷ A·cm⁻²sr⁻¹, high-throughput of at least 1.6 μA for the electrons, and less than 50 femtosecond temporal resolution imaging of the specimen.

11. The method of claim 9, further comprising:
using a sequence of the laser output, triggered by a first laser;
tuning the sequence with the radio frequency cavity acting as a lens; and
obtaining simultaneous measurements with both photon and electron probes in order to observe dynamic events in the specimen initiated by a pump laser output.

12. The method of claim 9, further comprising a programmable controller automatically synchronizing dual-probe timing in less than 50 femtosecond precision using optical delay stages and causing digital delay sequences at multi-GHz frequencies.

13. The method of claim 9, further comprising using a field-programmable gate array, paired with a data converter that interfaces directly with the radio frequency cavity, to suppress local phase noise within a bandwidth of the radio frequency cavity.

14. The method of claim 9, further comprising electrical circuitry using at least two phase-locked loops of which a digital and higher speed loop is used for the suppressing step, and an analog and lower speed loop is used for the deterring step, wherein the digital loop serves as a master feedback loop overseeing an entire radio frequency circuit and feeds phase corrections into the analog loop.

15. The method of claim 9, further comprising:
constantly feeding a fixed radio frequency signal into the radio frequency cavity, when the electron microscope is operating;
detecting a radio frequency field from the radio frequency cavity;
measuring a phase difference between an incident signal and the detected signal from the radio frequency cavity;
shifting a resonance frequency of the radio frequency cavity when a temperature of the radio frequency cavity varies;
detecting the phase difference when the temperature varies; and
automatically adjusting a thermal actuator when the temperature varies, which automatically changes heating or cooling of the radio frequency cavity.

16. The method of claim 9, further comprising using a cascade-loop in at least one programmable controller which includes a cavity phase-locked sub-loop which maintains radio frequency cavity resonance without mechanical tuners, and an amplitude control sub-loop to ensure stability of a field within the radio frequency cavity.

17. The method of claim 9, further comprising:
using a cascade-loop in at least one programmable controller which includes a first sub-loop where ultrafast dynamics are probed using a femtosecond electron pulse, where the first sub-loop introduces temporal delays via optical delay stages, and a second sub-loop which probes over an entire pump period with an optical probe laser operating at ≥80 MHz repetition rates; and
using a shared pump laser to initiate both sub-loops simultaneously;
wherein the second sub-loop captures every of the pulse at fixed intervals using a streaming data acquisition system, and applies electronically gated acquisition to select and record only specific probe pulses at faster delay increments within each pump cycle.

18. A method of using an electron microscope, the method comprising:
(a) emitting a laser output to a photogun;
(b) sending electrons from the photogun to a radio frequency cavity;
(c) sending the electron bunch from the radio frequency cavity;
(d) constantly feeding a fixed radio frequency signal into the radio frequency cavity, when the electron microscope is operating;
(e) detecting a radio frequency field from the radio frequency cavity;
(f) measuring a phase difference between an incident signal and the detected field from the radio frequency cavity;
(g) shifting a resonance frequency of the radio frequency cavity when a temperature of the radio frequency cavity varies;
(h) detecting the phase difference when the temperature varies; and
(i) automatically adjusting heating or cooling of the radio frequency cavity when the temperature varies.

19. The method of claim 18, wherein:
using a phase detector for the detecting the radio frequency field;
using a direction coupler for the measuring;
detecting a voltage output change from the phase detector, which corresponds to the phase difference, when the temperature varies;
automatically comparing the detected voltage output change to a desired value; and
automatically adjusting a thermal actuator in response to the comparison for the adjusting of the heating or the cooling of the radio frequency cavity.

20. The method of claim 18, wherein the thermal actuator includes fluid conduits in a wall of the radio frequency cavity, and energizable heat sink fins projecting from an outside of the radio frequency cavity.

21. A method of using an electron microscope comprising using the electron microscope for ultrafast electron imaging by generating an electron probe using a laser-driven photocathode operated at a repetition rate in the MHz to GHz range, and delivering the electron probe to a specimen to obtain high-brightness of at least 3.67×10⁷ A·cm⁻²sr⁻¹, an electron-bunch throughput of at least 1.6 μA, and femtosecond-scale temporal-resolution imaging, wherein the brightness and beam current scale substantially linearly with the laser repetition rate.

22. The method of claim 21, further comprising operating a drive laser in a MHz regime yields proportionally scaled performance, including reduced brightness and throughput that remain linearly proportional to an operating repetition rate while preserving femtosecond-scale temporal resolution.

23. The method of claim 21, further comprising using a programmable controller to automatically synchronize dual-probe timing in less than 50 femtosecond precision using optical delay stages and causing digital delay sequences at multi-GHz frequencies.

24. The method of claim 21, further comprising using a programmable logic device integrated circuit, with logic gates, paired with a data converter that interfaces directly with a radio frequency cavity to suppress local phase noise within a bandwidth of the radio frequency cavity.

25. The method of claim 21, further comprising electrical circuitry using at least two phase-locked loops of which a digital and higher speed loop is used for suppressing low-frequency disturbances in an electron bunch, and an analog and lower speed loop is used for controlling high-frequency radio frequency jitters to reduce noise in the electron bunch, wherein the digital loop serves as a master feedback loop overseeing an entire radio frequency circuit and feeds phase corrections into the analog loop.

26. An electron microscope apparatus comprising:
(a) a drive laser configured to emit a laser pulse;
(b) a photocathode configured to receive the laser beam pulse and emit electrons;
(c) a radio frequency cavity configured to change a characteristic of the emitted electrons from the photocathode;
(d) a specimen holder configured to hold the specimen while it receives the electrons from the radio frequency cavity;
(e) a detector configured to create an image of the specimen;
(f) at least one programmable controller configured to automatically:
suppress low-frequency disturbances in the electrons;
control high-frequency radio frequency jitters to reduce noise in the electrons;
overlap the suppression and the jitters control in a frequency region to cancel undesired electrical or photonic noise in all frequencies; and
coordinate laser-to-laser and laser-to-radio frequency synchronization.
